(19) United States
(12) Patent Application Publication
(10) Pub. No.: US 2025/0172876 A1
(43) Pub. Date: May 29, 2025

(54) DEVELOPER TOLERANCE RESIST UNDERLAYER COMPOSITION AND METHOD FOR MANUFACTURING RESIST PATTERN

(71) Applicant: Merck Patent GMBH, Darmstadt (DE)

(72) Inventors: Hiroshi Yanagita, Shizuoka (JP); Kazuma Yamamoto, Shizuoka (JP); Masato Suzuki, Shizuoka (JP)

(21) Appl. No.: 19/033,723

(22) Filed: Jan. 22, 2025

Related U.S. Application Data
(63) Continuation of application No. PCT/EP2023/069974, filed on Jul. 19, 2023.

(30) Foreign Application Priority Data
Jul. 22, 2022 (JP) 2022-117341

(51) Int. Cl. G03F 7/09; C08K 5/3492; C08K 5/375; C08K 5/42; G03F 7/16

(52) U.S. Cl. CPC G03F 7/094; C08K 5/34922; C08K 5/375; C08K 5/42; G03F 7/168; C08K 2201/014

(57) ABSTRACT

A developer tolerant resist underlayer composition includes a polymer (A), a cross-linking agent (B), a thermal acid generator (C) and a solvent (D):
wherein the polymer (A) comprises at least a unit having a protective group that is deprotected by an acid, and the hydrophilicity of the portion where the deprotected unit is present changes after exposure.

### CROSS-REFERENCE TO RELATED APPLICATION

This application is a Continuation under 35 USC § 111(a) of International Patent Application No. PCT/EP2023/069974, filed Jul. 19, 2023, which claims priority to the JP Application No. 2022-117341, filed Jul. 22, 2022. The entire contents of these applications are incorporated herein by reference in their entirety.

### BACKGROUND OF THE INVENTION

### Technical Field

The present invention relates to a developer tolerant resist underlayer composition. The present invention also relates to a method for manufacturing a resist pattern.

### Background Art

In a process of manufacturing devices such as semiconductors, fine processing by lithographic technology using a photoresist has generally been employed. The wavelength used for exposure is continually becoming shorter, and a lithographic technique using extreme ultraviolet (EUV) with a wavelength of 13.5 nm is under consideration.

Under conventional exposure conditions of wavelengths of 248 nm and 193 nm, a chemically amplified resist composition is used as the resist material. When EUV is used, a variety of resist materials are being considered, one of which is a metal-containing resist as disclosed in JP 2021-73367 A.

In the lithographic process, there is a problem that the dimensional accuracy of the photoresist pattern deteriorates due to the influence of standing waves caused by the reflection of light from the substrate and the influence of irregular reflection of the exposure light due to the level difference of the substrate. Therefore, in order to solve this problem, methods of providing a resist underlayer have been widely studied. A resist underlayer that can be developed with an alkaline developer simultaneously with the resist film has also been proposed as disclosed in WO 2011/086757.

### SUMMARY OF THE INVENTION

### Problems to be Solved by the Invention

The present inventors got an idea that a film formed from a metal-containing resist composition changes in its surface's physical properties before and after exposure. In particular, in the exposed area, the hydrophilicity changes before and after exposure.

The inventors have considered that there are one or more problems still in need of improvements. They include, for example, the following:

The resist pattern tends to collapse; the resist underlayer has low solvent resistance; the film thickness reduction of the resist underlayer occurs due to the resist composition; the resist underlayer is dissolved by a developer; and adhesion to a substrate is reduced due to the change in the hydrophilicity of the resist film.

The present invention has been made based on the technical background as described above, and provides a resist underlayer composition.

### Means for Solving the Problems

The developer tolerant resist underlayer composition according to the present invention comprises a polymer (A), a cross-linking agent (B), a thermal acid generator (C) and a solvent (D), and
the polymer (A) is one that comprises at least a unit having a protective group that is deprotected by an acid, and the hydrophilicity of the portion where the deprotected unit is present changes after exposure.

A method for manufacturing a resist pattern according to the present invention comprises the following steps:
(1) applying a resist underlayer composition above a substrate and heating the resist underlayer composition to form a resist underlayer;
(2) applying a resist composition directly on the resist underlayer and heating the resist composition to form a resist film;
(3) exposing the resist film;
(4) optionally, performing a post-exposure bake of the resist film; and
(5) developing the resist film using a developer to form a resist pattern, provided that the resist underlayer is not developed by the developer:
wherein
when the contact angle of the resist film before exposure is defined as θ_{PrR}, that of the resist film after exposure is defined as θ_{PeR}, that of the resist underlayer before exposure is defined as θ_{PrU}, and that of the resist underlayer after exposure is defined as θ_{PeU},
   θ_{PeU}/θ_{PrU}<1.0 when θ_{PeR}/θ_{PrR}<1.0, and
   θ_{PeU}/θ_{PrU}>1.0 when θ_{PeR}/θ_{PrR}>1.0,
wherein the contact angle is measured using water.

A method for manufacturing a device according to the present invention comprises the method above described.

### Effects of the Invention

According to the present invention, one or more of the following effects can be desired.

The resist pattern collapse can be suppressed; the resist underlayer has sufficient solvent resistance; the film thickness reduction due to the resist composition is suppressed; the dissolution of the resist underlayer due to the developer is suppressed; the acid generated from the thermal acid generator (C) accelerates the cross-linking reaction between the polymer (A) and the cross-linking agent (B) to impart developer tolerance to the resist underlayer; an acid generated by the photoacid generation part (E) with receipt of light selectively deprotects the polymer (A), thereby changing the hydrophilicity of the polymer (A); the acid generated from the photoacid generator present in the resist film moves to the resist underlayer film and selectively deprotects the polymer (A), thereby changing the hydrophilicity of the polymer (A); it is possible to match the change in the hydrophilicity of the resist underlayer with the change in the hydrophilicity of the resist film; and since the exposed area and the unexposed area of the resist underlayer are physically connected also after development, even if affinity with the substrate is decreased in a part of the resist underlayer, it is possible to maintain adhesion to the substrate as a whole resist underlayer film.

### DETAILED DESCRIPTION OF THE INVENTION

### Mode for Carrying Out the Invention

### Definition

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and unit thereof are common. For example, 5 to 25 mol % means 5 mol % or more and 25 mol % or less.

The descriptions such as “C_{x-y}”, “C_{x-Cy}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When polymer has a plural types of repeating unit, these repeating unit copolymerize. These copolymerization may be any of alternating copolymerization, random copolymerization, block copolymerization, graft copolymerization, or a mixture thereof. When polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (D) or another component.

### BEST MODE FOR CARRYING OUT THE INVENTION

Hereinafter, embodiments of the present invention are described in detail.

### Developer Tolerant Resist Underlayer Composition

The developer tolerant resist underlayer composition according to the present invention (hereinafter sometimes referred to as the composition) comprises a polymer (A), a cross-linking agent (B), a thermal acid generator (C) and a solvent (D), and
the polymer (A) is one that comprises at least a unit having a protective group that is deprotected by an acid, and the hydrophilicity of the portion where the deprotected unit is present changes after exposure.

In the present invention, the developer tolerant resist underlayer composition is a composition that forms a resist underlayer having tolerance to developer. The resist underlayer is formed above a substrate and immediately below a resist film.

An interlayer may be interposed between the resist underlayer and the substrate. The resist underlayer of the present invention is preferably a substrate adhesion enhancing film. The resist underlayer of the present invention may have antireflection performance for light used in exposure. That is, the resist underlayer of the present invention may be an antireflection film.

The developer preferably comprises an organic solvent and more preferably consists of an organic solvent.

Preferably, the developer is one that develops a resist layer but does not develop any resist underlayer. As an embodiment of the present invention, when the developer is paddled on the resist underlayer for 30 seconds, the amount of decrease in the thickness of the resist underlayer is preferably 0 to 30% (more preferably 0 to 10%; further preferably 0.1 to 10%; further more preferably 0.1 to 5%), and/or preferably 5 nm or less (more preferably 0 to 5 nm; further preferably 0.1 to 3 nm; further more preferably 0.1 to 2 nm).

### Polymer (A)

The composition according to the present invention comprises a polymer (A). The polymer (A) comprises at least a unit having a protective group that is deprotected by an acid, and the hydrophilicity of the portion where the deprotected unit is present changes after exposure. In particular, the polymer (A) is hydrophobic before exposure and becomes hydrophilic after exposure, or is hydrophilic before exposure and becomes hydrophobic after exposure. Preferably, it is hydrophobic before exposure and changes to hydrophilic after exposure. The change in hydrophobicity or hydrophilicity can be measured by the contact angle of water dropped on the film. This is described later.

The polymer (A) preferably comprises the unit (A1) represented by the formula (a1).

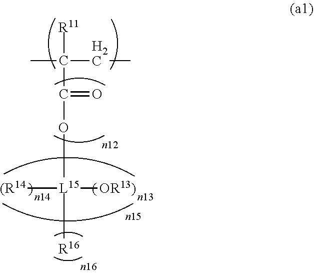

The unit (A1) preferably has a protective group that is deprotected by an acid, and is deprotected after exposure.

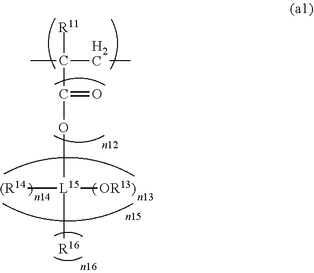

In the formula:
R¹¹ is each independently H or methyl (preferably H).
L¹⁵ is each independently a C₆₋₂₀ aromatic hydrocarbon group or a C₁₋₆ saturated hydrocarbon group (preferably a C₆₋₂₀ aromatic hydrocarbon group; more preferably cyclohexyl). As an embodiment of the present invention, L₁₅ is each independently preferably phenyl or cyclohexyl.
R¹³ is each independently tert-butyl or C₅₋₁₀ alkyl (where the methylene in the alkyl may be replaced with oxy and/or carbonyl). In this specification, tert-butyl is sometimes described as t-Bu or tBu. R₁₃ is preferably t-Bu or —C(═O)—O-tBu (more preferably t-Bu).
R¹⁴ is each independently C₁₋₅ alkyl (preferably methyl, ethyl, i-propyl or n-propyl; more preferably methyl).
R¹⁶ is each independently t-Bu or C₅₋₁₅ alkyl (preferably t-Bu, 1-methylcyclopentyl, 1-ethylcyclopentyl, 1-methyladamantyl, 1-ethyladamantyl or 1-ethylcyclohexyl; more preferably t-Bu, 1-ethylcyclopentyl, 1-ethyladamantyl or 1-ethylcyclohexyl; further preferably t-Bu or 1-ethylcyclopentyl; further more preferably t-Bu). R¹⁶ that is C₅₋₁₅ alkyl may not be reduced, or be reduced to form a saturated hydrocarbon group.
n12, n15 and n16 are each independently a number of 0 to 1 (preferably each independently 0 or 1). n12 is more preferably 1. As another embodiment of the present invention, n12 is more preferably zero.
n13 is each independently a number of 1 to 3 (preferably 1, 2 or 3; more preferably 1).
n14 is each independently a number of 0 to 4 (preferably 1, 2 or 3; more preferably 1).

Provided that n12=n16=1 when n15=0, and n16=0 when n15=1. Preferably, n15=0. It is also another preferred embodiment of the present invention that n16=0.

Exemplified embodiments of the unit (A1) include the following.

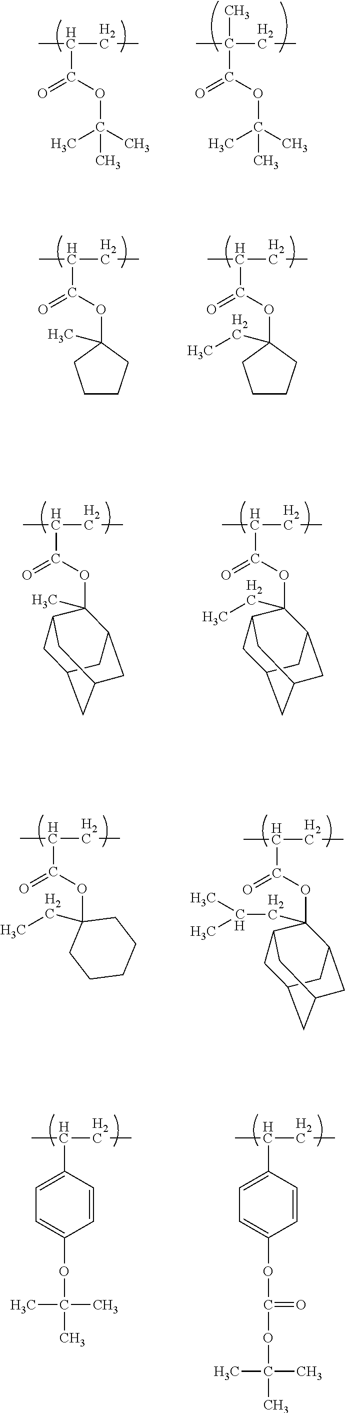

The structure below can be read in the unit (A1). In the formula (a1), when n12=n16=1, n15=0, R¹¹=H and R¹⁶=t-Bu, the following compound is obtained.

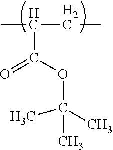

The structure below can be read in the unit (A1). In formula (a1), when n12=n16=0, n15=1, R¹¹=H, L¹⁵=phenyl, n14=0, n13=1 and R¹³=t-Bu, the following compound is obtained.

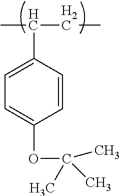

More preferably, the polymer (A) further comprises at least one of the unit (A2) represented by the formula (a2), the unit (A3) represented by the formula (a3), the unit (A4) represented by the formula (a4) and the unit (A5) represented by the formula (a5).

In a preferred embodiment, the polymer (A) comprises the unit (A1) represented by the formula (a1) and the unit (A2) represented by the formula (a2).

In a more preferred embodiment, the polymer (A) further comprises, in addition to the above, at least one of the unit (A3) represented by the formula (a3), the unit (A4) represented by the formula (a4) and the formula (a5) represented by the unit (A5).

The formula (a2) is as follows.

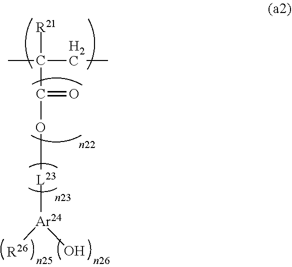

In the formula:
R²¹ is each independently H or methyl (preferably H).
L²³ is each independently C₁₋₁₀ alkylene (preferably methylene or ethylene).
Ar²⁴ is each independently C₆₋₂₀ aryl (preferably phenyl).
R²⁶ is each independently C₁₋₅ alkyl (preferably methyl or ethyl).
n22 and n23 are each independently a number of 0 to 1 (preferably 0 or 1; more preferably 0).
n25 is each independently a number of 0 to 4 (preferably 0 or 1; more preferably 0).
n26 is each independently a number of 1 to 3 (preferably 1 or 2: more preferably 1).

Exemplified embodiments of the unit (A2) include the following.

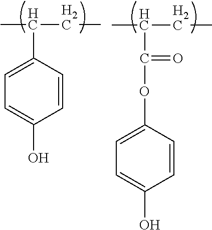

The formula (a3) is as follows.

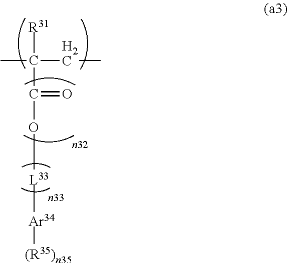

In the formula:
R³¹ is each independently H or methyl (preferably H).
L³³ is each independently C₁₋₁₀ alkylene (preferably methylene).
Ar³⁴ is each independently C₆₋₂₀ aryl (preferably phenyl).
R³⁵ is each independently —O—R^{35a}, —(C═O)—R^{35b}, —(C═O)—O—R^{35a}, —(C═O)—NR^{35c}R^{35d}, —O—(C═O)—R^{35e}, —NR^{35f}—(C═O)—R^{35g} or —R^{35j}OH (preferably —O—R^{35a}; more preferably methoxy).
n32 and n33 are each independently a number of 0 to 1 (preferably 0 or 1; more preferably 0).
n35 is each independently a number of 0 to 3 (preferably 0 or 1; more preferably 1).
R^{35a} is each independently C₁₋₄ alkyl (excluding tBu). R^{35a} is preferably methyl or ethyl (more preferably methyl).
R^{35b} is each independently H or C₁₋₄ alkyl (preferably methyl, ethyl, n-propyl or i-propyl; more preferably methyl).
R^{35c} and R^{35d} are each independently H or C₁₋₄ alkyl (preferably H, methyl, ethyl, n-propyl or i-propyl; more preferably H or methyl). When both R^{35c} and R^{35d} are alkyl, these may be combined to form a ring.
R^{35e} is each independently H, C₁₋₄ alkyl or C₁₋₄ alkoxy (excluding tert-butoxy) (preferably H, methyl, ethyl, n-propyl, i-propyl or methoxy; more preferably H, methyl or methoxy).
R^{35f} is each independently H or C₁₋₄ alkyl (preferably H, methyl, ethyl, n-propyl or i-propyl; more preferably H or methyl).
R^{35g} is each independently H, C₁₋₄ alkyl or —NR^{35h}R^{35r} (preferably H, methyl, ethyl, n-propyl, i-propyl or —NR^{35h}R^{35r}; more preferably H, methyl or —NR^{35h}R^{35r}).
R^{35h} and R^{35r} are each independently H or C₁₋₄ alkyl (preferably H, methyl, ethyl, n-propyl or i-propyl; more preferably H or methyl). When both R^{35h} and R^{35r} are alkyl, these may be combined to form a ring.
R^{35j} is each independently C₁₋₄ alkylene (preferably methylene or ethylene; more preferably methylene).

Exemplified embodiments of the unit (A3) include the following.

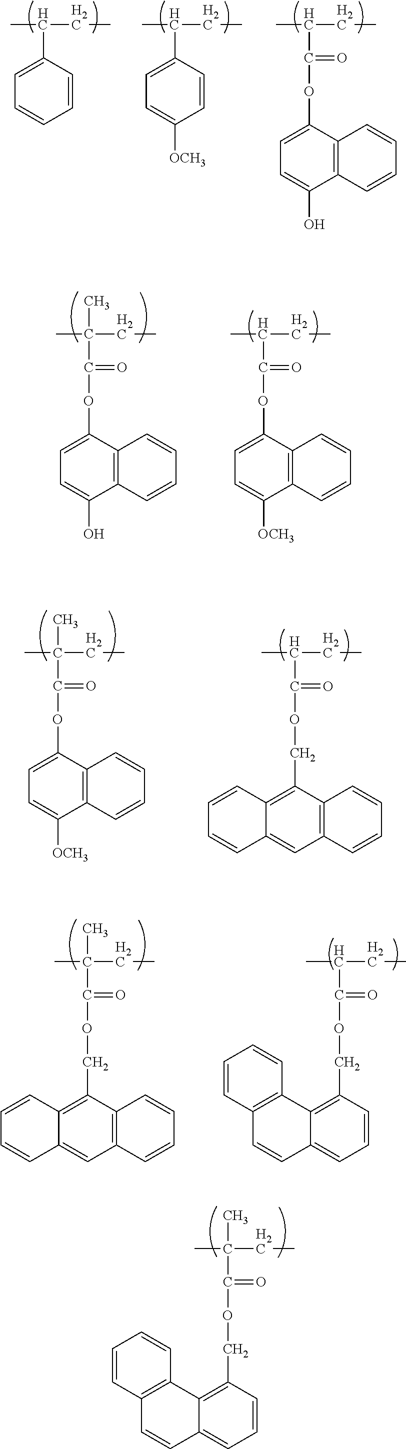

The formula (a4) is as follows.

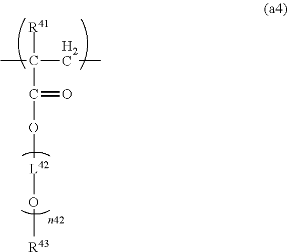

In the formula:
R⁴¹ is each independently H or methyl (preferably methyl).
L⁴² is C₁₋₄ alkylene (preferably methylene).
n42 is a number of 0 to 1 (preferably 0 or 1; more preferably 0).
R⁴³ is C₁₋₄ alkyl (excluding tBu) or the following group (preferably methyl, ethyl, n-propyl, i-propyl or the following group; more preferably methyl or the following group; more preferably the following group):

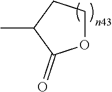

where
n43 is a number of 1 to 2 (preferably 1 or 2; more preferably 1).

Exemplified embodiments of the unit (A4) include the following.

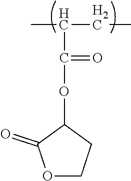

The formula (a5) is as follows.

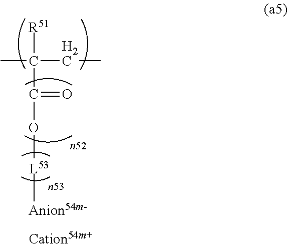

In the formula:
R⁵¹ is each independently H or methyl (preferably methyl).
L⁵³ is each independently C₁₋₁₀ alkylene (preferably C₁₋₄ alkylene; more preferably linear C₁₋₄ alkylene; further preferably methylene or ethylene).
n52 and n53 are each independently a number of 0 to 1,
n52 is preferably 0 or 1 (more preferably 1).
n53 is preferably 0 or 1 (more preferably 0).
Anion^{54m-} is an m-valent anion that is bonded upward in the formula, preferably an anion of the formula (E1) of the photoacid generator (E) described later.
Cation^{54m+} is an m-valent cation that is ionically bonded with Anion^{54m-}, preferably a cation of the formula (E1).
m is a number of 1 to 2 (preferably 1 or 2; more preferably 1).

Exemplified embodiments of the unit (A5) include the following.

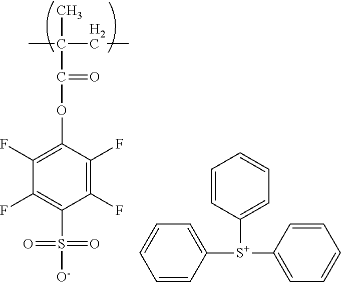

The number of repetitions of the unit (A1), the unit (A2), the unit (A3), the unit (A4) and the unit (A5) are taken as nA1, nA2, nA3, nA4 and nA5, respectively.
nA1/(nA1+nA2+nA3+nA4+nA5) is preferably 5 to 100% (more preferably 10 to 60%; further preferably 20 to 50%; further more preferably 25 to 45%).
nA2/(nA1+nA2+nA3+nA4+nA5) is preferably 0 to 95% (more preferably 10 to 90%; further preferably 30 to 80%; further more preferably 40 to 75%).
nA3/(nA1+nA2+nA3+nA4+nA5) is preferably 0 to 95% (more preferably 0 to 30%; further preferably 0 to 20%; further more preferably 5 to 20%). It is also a preferred embodiment of the present invention that nA3/(nA1+nA2+nA3+nA4+nA5) is 0%.
nA4/(nA1+nA2+nA3+nA4+nA5) is preferably 0 to 95% (more preferably 0 to 30%; further preferably 0 to 20%; further more preferably 5 to 20%). It is also a preferred embodiment of the present invention that nA4/(nA1+nA2+nA3+nA4+nA5) is 0%.
nA5/(nA1+nA2+nA3+nA4+nA5) is preferably 0 to 95% (more preferably 0 to 30%; further preferably 0 to 20%; further more preferably 1 to 10%). It is also a preferred embodiment of the present invention that nA5/(nA1+nA2+nA3+nA4+nA5) is 0%.

As a preferred embodiment of the present invention, one that satisfies the following is included:

$$5 \% \leq nA 1 / ( nA 1 + nA 2 + nA 3 + nA 4 + nA 5 ) \leq 100 \% ,$$

$$0 \% \leq nA 2 / ( nA 1 + nA 2 + nA 3 + nA 4 + nA 5 ) \leq 95 \% ,$$

$$0 \% \leq nA 3 / ( nA 1 + nA 2 + nA 3 + nA 4 + nA 5 ) \leq 95 \% ,$$

$$0 \% \leq nA 4 / ( nA 1 + nA 2 + nA 3 + nA 4 + nA 5 ) \leq 95 \% , and$$

$$0 \% \leq nA 5 / ( nA 1 + nA 2 + nA 3 + nA 4 + nA 5 ) \leq 95 \% .$$

The total number of all repeating units contained in the polymer (A) is taken as nₜₒₜₐₗ.
(nA1+nA2+nA3+nA4+nA5)/nₜₒₜₐₗ is preferably 80 to 100% (more preferably 90 to 100%; further preferably 95 to 100%).

Being (nA1+nA2+nA3+nA4+nA5)/nₜₒₜₐₗ=100%, that is, not containing any repeating unit other than the unit (A1), the unit (A2), the unit (A3), the unit (A4) and the unit (A5) is also a preferred embodiment of the present invention.

A preferred embodiment of the present invention is that when any one of nA3, nA4 and nA5 is greater than 0, the other two are 0.

The mass average molecular weight (hereinafter sometimes referred to as Mw) of the polymer (A) is preferably 2,000 to 50,000 (more preferably 2,500 to 30,000; further preferably 3,000 to 20,000).

The polydispersity index Mw/Mn (PDI) of the polymer (A) is preferably 1.0 to 2.0 (more preferably 1.4 to 1.9).

In the present invention, Mw and Mn can be measured by gel permeation chromatography (GPC). In this measurement, it is a preferred example to use a GPC column at 40 degrees Celsius, an eluent that is tetrahydrofuran at 0.6 mL/min and monodispersed polystyrene as a standard.

The content of the polymer (A) is preferably 0.1 to 10 mass % based on the total mass of the composition (more preferably 0.1 to 2 mass %; further preferably 0.1 to 1 mass %; further more preferably 0.2 to 0.5 mass %).

The content of the polymer (A) is preferably 40 to 90 mass % (more preferably 50 to 80 mass %; further preferably 70 to 80 mass %) based on the sum of other components excluding the solvent (D).

The method for synthesizing the polymer (A) is not particularly limited, but exemplified embodiments are described later in Synthesis Examples of Examples. It is also possible to combine Synthesis Examples with any known synthesis method.

### Cross-Linking Agent (B)

The composition according to the present invention comprises a cross-linking agent (B). Although not to be bound by theory, it can be thought that the cross-linking agent is useful for improving the film-forming properties of the composition when forming a film and prohibiting intermixing with the resist film that is formed thereonto to prohibit the diffusion of low-molecular-weight components into the over layer.

Examples of the cross-linking agent include melamine compounds, guanamine compounds, glycoluryl compounds or urea compounds substituted by at least one group selected from a methylol group, an alkoxymethyl group and an acyloxymethyl group; epoxy compounds; thioepoxy compounds; isocyanate compounds; azide compounds; and compounds containing a double bond such as an alkenyl ether group. Compounds containing a hydroxy group can also be used as the cross-linking agent.

Examples of the epoxy compound include tris(2,3-epoxypropyl) isocyanurate, trimethylolethane triglycidyl ether, trimethylolpropane triglycidyl ether, trimethylolethane triglycidyl ether, and the like.

Examples of the melamine compound include compounds derived by methoxymethylation of 1 to 6 methylol groups of hexamethylolmelamine, hexamethoxymethylmelamine or hexamethylolmelamine, and mixtures thereof; and compounds derived by acyloxymethylation of 1 to 6 methylol groups of hexamethoxymethylmelamine, hexaacyloxymethylmelamine or hexamethylolmelamine, or mixtures thereof.

Examples of the guanamine compound include compounds derived by methoxymethylation of 1 to 4 methylol groups of tetramethylolguanamine, tetramethoxymethylguanamine or tetramethylolguanamine, and mixtures thereof; and compounds derived by acyloxymethylation of 1 to 4 methylol groups of tetramethoxyethylguanamine, tetraacyloxyguanamine or tetramethylolguanamine, and mixtures thereof.

Examples of the glycoluryl compound include compounds derived by methoxymethylation of 1 to 4 methylol groups of tetramethylolglycoluril, tetramethoxyglycoluril, tetramethoxymethylglycoluril or tetramethylolglycoluril, or mixtures thereof, and compounds derived by acyloxymethylation of 1 to 4 methylol groups of tetramethylolglycoluril, or mixtures thereof.

Examples of the urea compound include compounds derived by methoxymethylation of 1 to 4 of methylol groups of tetramethylurea, tetramethoxymethylurea or tetramethylurea, or mixtures thereof; tetramethoxyethylurea, and the like. Examples of the compound containing an alkenyl ether group include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, trimethylolpropane trivinyl ether, and the like.

In a preferred embodiment, the cross-linking agent (B) is represented by the formula (b1):

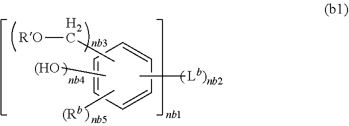

In the formula:
nb1 is 1, 2, 3 or 4 (preferably 1, 2 or 3; more preferably 1 or 2;

further preferably 1).
nb2 is 0 when nc1 is 1, and 1 when nc1 is 2 or more.
nb3 is 0, 1 or 2 (preferably 2).
nb4 is 1 or 2 (preferably 1).
nb5 is 0 or 1 (preferably 1).
L^{b} is a single bond or a C₁₋₃₀ hydrocarbon group (preferably a single bond, C₁₋₂₀ alkylene or C₆₋₃₀ arylene; more preferably a single bond).
R^{b} is each independently C₁₋₆ alkyl (where the methylene in the alkyl may be replaced with oxy) or C₆₋₁₀ aryl (preferably methyl or phenyl).
R′ is H or methyl (preferably methyl).

Examples of the cross-linking agent (B) include the following.

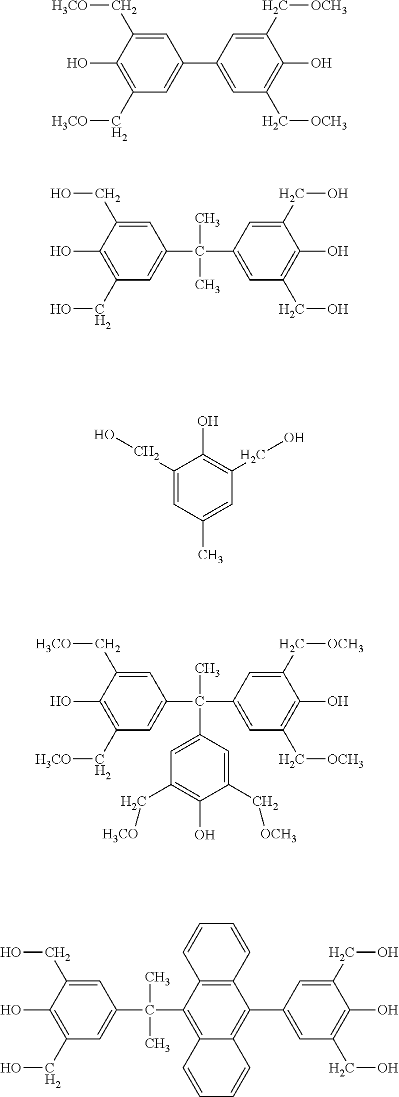 [SMILES: COCc1cc(-c2cc(COC)c(O)c(COC)c2)cc(COC)c1O ; CC(C)(c1cc(CO)c(O)c(CO)c1)c1cc(CO)c(O)c(CO)c1 ; Cc1cc(CO)c(O)c(CO)c1 ; COCc1cc(C(C)(c2cc(COC)c(O)c(COC)c2)c2cc(COC)c(O)c(COC)c2)cc(COC)c1O ; CC(C)(c1cc(CO)c(O)c(CO)c1)c1c2ccccc2c(-c2cc(CO)c(O)c(CO)c2)c2ccccc12]

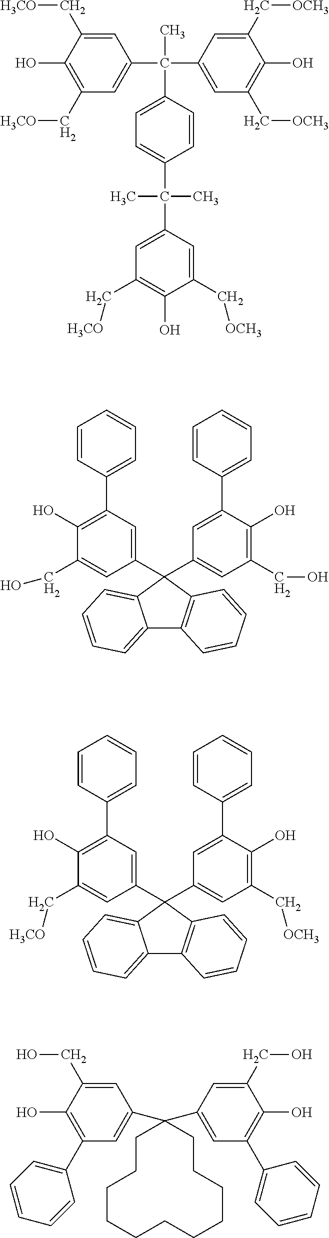 [SMILES: COCc1cc(C(C)(C)c2ccc(C(C)(c3cc(COC)c(O)c(COC)c3)c3cc(COC)c(O)c(COC)c3)cc2)cc(COC)c1O ; OCc1cc(C2(c3cc(CO)c(O)c(-c4ccccc4)c3)c3ccccc3-c3ccccc32)cc(-c2ccccc2)c1O ; COCc1cc(C2(c3cc(COC)c(O)c(-c4ccccc4)c3)c3ccccc3-c3ccccc32)cc(-c2ccccc2)c1O ; OCc1cc(C2(c3cc(CO)c(O)c(-c4ccccc4)c3)CCCCCCCCCCC2)cc(-c2ccccc2)c1O]

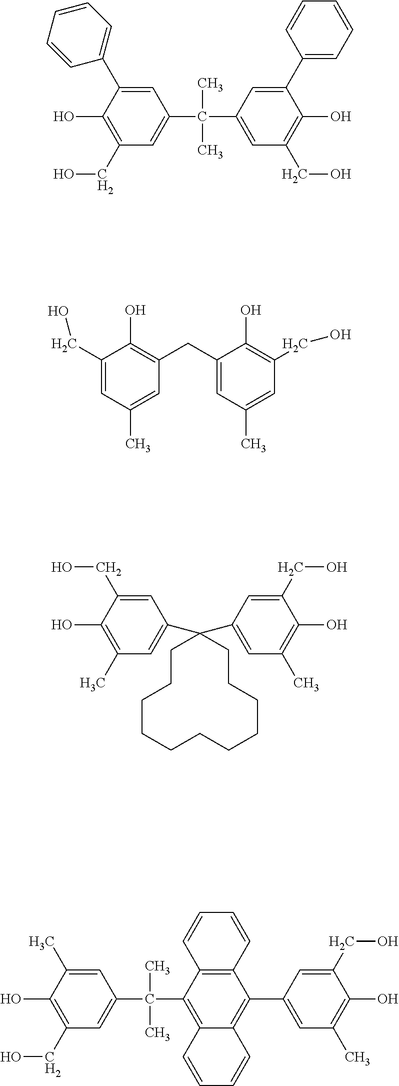 [SMILES: CC(C)(c1cc(CO)c(O)c(-c2ccccc2)c1)c1cc(CO)c(O)c(-c2ccccc2)c1 ; Cc1cc(CO)c(O)c(Cc2cc(C)cc(CO)c2O)c1 ; Cc1cc(C2(c3cc(C)c(O)c(CO)c3)CCCCCCCCCCC2)cc(CO)c1O ; Cc1cc(-c2c3ccccc3c(C(C)(C)c3cc(C)c(O)c(CO)c3)c3ccccc23)cc(CO)c1O]

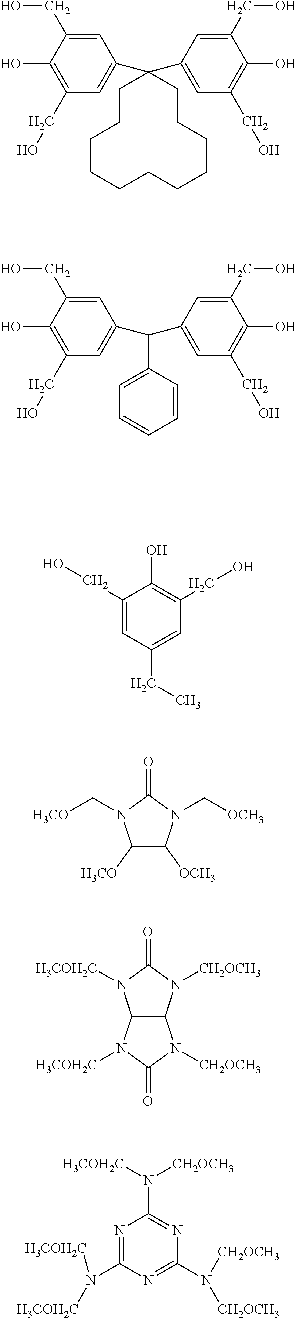

The cross-linking agent (B) may be one type or two or more types (more preferably one type).

The content of the cross-linking agent (B) is preferably 5 to 100 mass % (more preferably 10 to 50 mass %; further preferably 20 to 40 mass %) based on the total mass of the polymer (A).

### Thermal Acid Generator (C)

The composition according to the present invention comprises a thermal acid generator (C). The thermal acid generator generates an acid by heat. Preferably, the acid derived from (C) accelerates the cross-linking reaction of the polymer (A) and the cross-linking agent (B).

The pKa (H₂O) of the acid generated from the thermal acid generator (C) is preferably 1 to 8 (more preferably 2 to 6). In one preferred embodiment, the acid generated from the thermal acid generator (C) is a carboxylic acid. Although not to be bound by theory, it can be thought that the acid derived from (C) accelerates the cross-linking reaction of between (A) and (B), but does not deprotect the protective group of the polymer (A), thereby being able to control so as not all of the resist underlayer deprotected while maintaining developer tolerance.

Preferably, the thermal acid generator (C) is activated at a temperature above 80° C. Examples of the thermal acid generator (C) include metal-free, strongly non-nucleophilic alkylammoniums, dialkylammoniums and trialkylammoniums.

In a preferred embodiment, the thermal acid generator (C) is represented by the formula (c1).

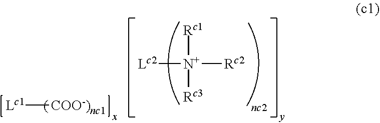

In the formula:
nc1 is 1 or 2 (preferably 2).
L^{c1} is H or C₁₋₆ alkyl when nc1 is 1, in which the alkyl may be substituted with halogen or hydroxy (preferably fluorine-substituted or unsubstituted C₁₋₆ alkyl; more preferably fluorine-substituted C₁₋₆ alkyl; further preferably fluorine-substituted ethyl). L^{c1} is C₁₋₄ alkylene when ne1 is 2, in which the alkylene may be substituted by halogen or hydroxy, and the methylene in the alkylene may be replaced with carbonyl, oxy or amido (preferably C₁₋₃ alkylene, in which the methylene in the alkylene may be replaced with carbonyl; more preferably methylene).
nc2 is 1 or 2 (preferably 1).
L^{c2} is C₁₋₆ alkyl when nc2 is 1, in which the alkyl may be substituted with halogen or hydroxy (preferably methyl or ethyl). L^{c2} is C₁₋₄ alkylene when nc2 is 1, in which the alkylene may be substituted with halogen or hydroxy, and the methylene in the alkylene may be replaced with carbonyl, oxy or amido (preferably methylene or ethylene).
R^{c1}, R^{c2} and R^{c3} are each independently H or C₁₋₁₀ alkyl, in which the alkyl may be substituted with halogen or hydroxy (preferably H, methyl or ethyl; more preferably methyl or ethyl; further preferably ethyl).
x and y are 1 or 2, provided that nc1 X=nc2 X y is satisfied. Preferably, x is 2 and y is 1.

Examples of the cation of the formula (c1) include the following.

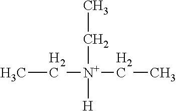

Examples of the anion of the formula (c1) include the following.

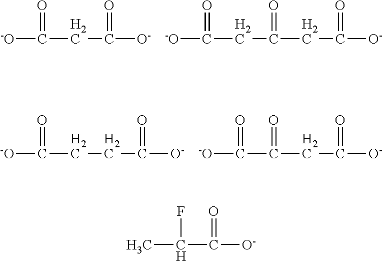

The thermal acid generator (C) may be one type or two or more types (more preferably one type).

The content of the thermal acid generator (C) is preferably 0.5 to 30 mass % (more preferably 1 to 15 mass %; further preferably 2 to 8 mass %) based on the total mass of the polymer (A).

### Solvent (D)

The composition according to the present invention comprises a solvent (D). The solvent (D) is preferably water, hydrocarbon solvents, ether solvents, ester solvents, alcohol solvents, ketone solvents, or any combination of any of these.

Exemplified embodiments of the solvent (D) include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4,2-methylpentanediol-2,4, hexanediol-2,5, heptanediol-2,4,2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, methyl n-pentyl ketone, ethyl n-butyl ketone, methyl n-hexyl ketone, di-i-butyl ketone, trimethylnonanone, cyclohexanone, cyclopentanone, methylcyclohexanone, 2,4-pentanedione, acetonylacetone, diacetone alcohol, acetophenone, fenthion, ethyl ether, i-propyl ether, n-butyl ether, n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran; ester-based solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), γ-butyrolactone, n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate and propylene glycol monopropyl ether acetate; N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of any two or more of these.

The solvent (D) is further preferably PGMEA, PGME, EL or any mixture thereof (further more preferably any mixture of PGMEA, PGME and EL).

In relation to other layers or films, it is also one embodiment that the solvent (D) does not contain water. For example, the amount of water in the whole solvent (D) is preferably 0.1 mass % or less (more preferably 0.01 mass % or less; further preferably 0.001 mass % or less). It is also a preferable embodiment of the present invention that the solvent (D) contains no water (0.000 mass %).

The content of the solvent (D) is preferably 80 to 99.99 mass % based on the total mass of the composition (more preferably 90 to 99.9 mass %; further preferably 95 to 99.9 mass %; further more preferably 99.0 to 99.8 mass %).

### Photoacid Generation Part (E)

The composition according to the present invention can further comprise a photoacid generation part (E). The photoacid generation part (E) is a part that generates an acid upon exposure. Preferably, the photoacid generation part (E) is a part of the polymer (A) or a component different from (A) to (D). More preferably, the photoacid generation part (E) is a part of the polymer (A), and (E) is incorporated into (A) as the unit (A5). In this specification, when (E) is incorporated into the unit (A5), it is calculated as the content of the polymer (A). That is, in this case, the content of (E) is 0 mass %.

The composition according to the present invention can further comprise a photoacid generator (F). The photoacid generator (F) is a component that generates an acid upon exposure. In one preferred embodiment, the photoacid generator (F) is a component different from (A) to (D). As one preferred embodiment, the photoacid generation part (E) is the photoacid generator (F).

Although not to be bound by theory, it can be thought that the photoacid generation part (E) generates an acid, which acts on the polymer (A) to deprotect, thereby the hydrophilicity of the polymer (A) easily changes.

The pKa (H₂O) of the acid generated from the photoacid generation part (E) is preferably −20 to 3 (more preferably −20 to 1).

The pKa (H₂O) of the acid generated from the thermal acid generator (C) is preferably greater than the pKa (H₂O) of the acid generated from the photoacid generation part (E). Although not to be bound by theory, it can be thought that the acid derived from (E) deprotects the protective group of the polymer (A), thereby making it possible to selectively change the hydrophilicity of the exposed area or unexposed area of the resist underlayer.

The photoacid generation part (E) is preferably represented by the formula (E1).

Anion^{54m-} Cation^{54m+} (E1)

Provided that when the photoacid generation part (E) is a part of the polymer (A), H or F in Anion^{54m-} is substituted and such a part is bonded with other part of the polymer (A).

In the formula:
Anion^{54m-} is an anion selected from the group consisting of an anion represented by the formula (ea1) and an anion represented by the formula (ea2) (preferably an anion represented by the formula (ea1)). Anion^{54m-} is m-valent as a whole.
Cation^{54m+} is a cation selected from the group consisting of a cation represented by the formula (ec1), a cation represented by the formula (ec2) and a cation represented by the formula (ec3) (preferably a cation represented by the formula (ec1)). Cation^{54m+} is m-valent as a whole.

The formula (ea1) is as follows.

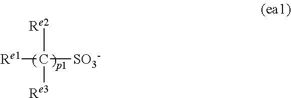

In the formula:
R^{e1} is a C₄₋₃₀ hydrocarbon group containing a ring structure having 5 or more ring atoms, in which at least one of the ring atoms may be nitrogen, the hydrocarbon group may be substituted with nitro, hydroxy, halogen, —OSO₂—R^{e4}, —SO₂—R^{e4}, —OR^{e4}, —COOR^{e4}, —O—CO—R^{e4}, —O—R^{e5}—COOR^{e4}, —R^{e5}—CO—R^{e4} or —S—R^{e5}, and —CH₂— in the hydrocarbon group may be replaced with carbonyl, ether, carbonyloxy, sulfide, thiocarbonyl or sulfonyl. R^{e1} is preferably phenyl optionally substituted with C₁₋₃ alkyl (more preferably phenyl or tolyl; further preferably tolyl).
R^{e2} and R^{e3} are each independently H, fluorine, fluorine-substituted C₁₋₅ alkyl or C₁₋₅ alkyl (preferably H, fluorine, trifluoromethyl or methyl; more preferably fluorine or trifluoro methyl).
R^{e4} is each independently a C₁₋₁₀ hydrocarbon group (preferably methyl, ethyl, i-propyl, n-propyl, tBu, cyclopentyl, cyclohexyl or adamantanyl).
R^{e5} is each independently a single bond or a C₁₋₁₀ hydrocarbon group (preferably H, methyl, ethyl, i-propyl, n-propyl, tBu, cyclopentyl, cyclohexyl or adamantyl).
p1 is each independently a number of 0 to 10 (preferably an integer of 0 to 4; more preferably an integer of 0 to 3; further preferably 0, 1 or 2; further more preferably 0).

Exemplified embodiments of the formula (ea1) include the following.

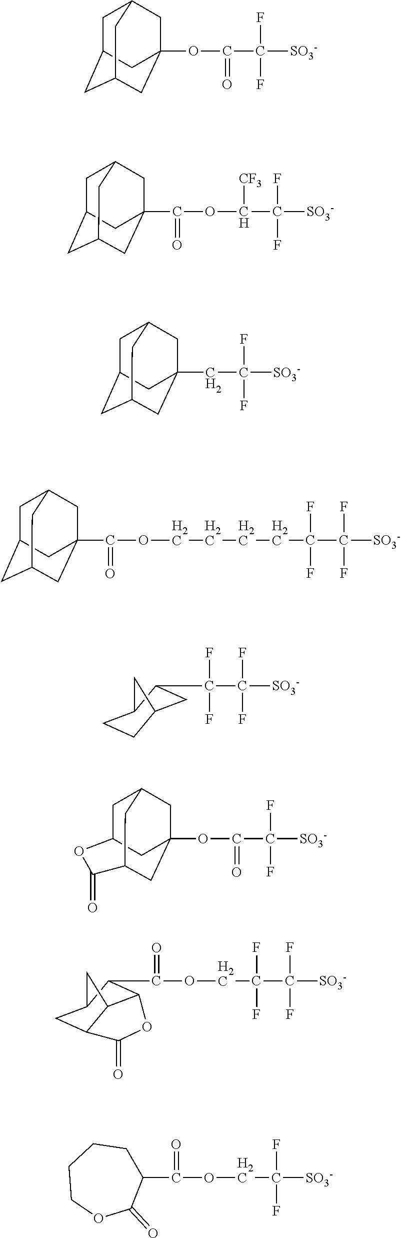

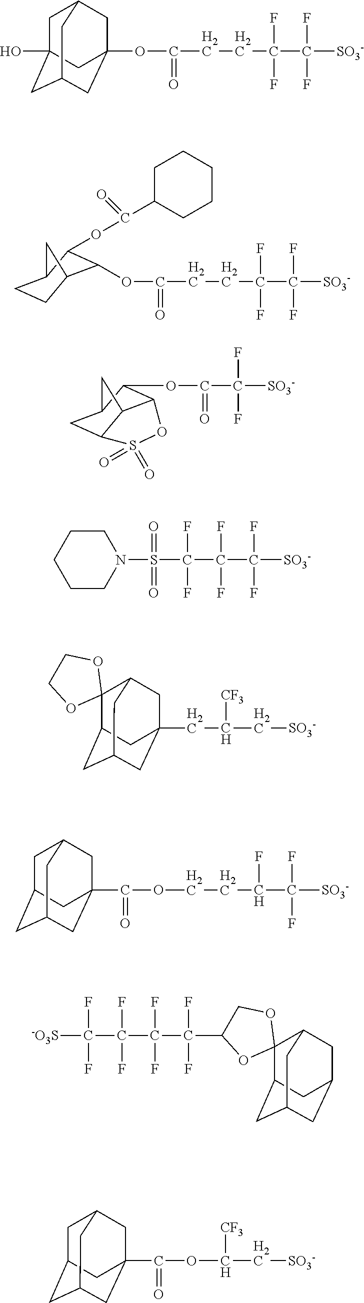

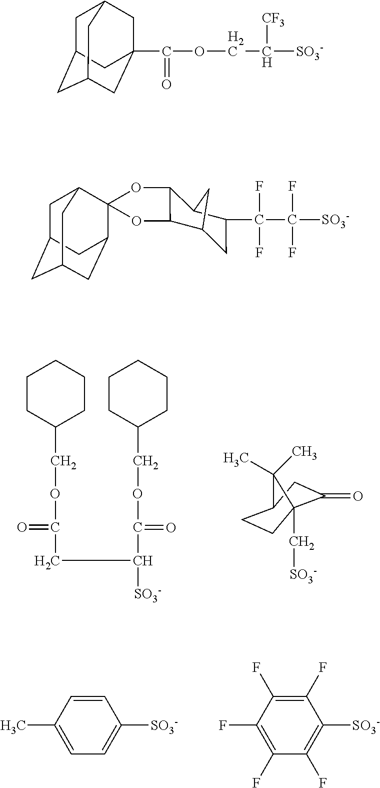

The formula (ea2) is as follows.

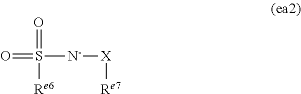

In the formula:
X is carbonyl or sulfonyl.
R^{e6} and R^{e7} are each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, in which R^{e6} and R^{e7} may be bonded to each other to form a fluorine-substituted heterocyclic structure, preferably C₁₋₃ fluorine-substituted alkyl. When forming a heterocyclic structure, it is preferably a 6-membered ring.

Exemplified embodiments of the formula (ea2) include the following.

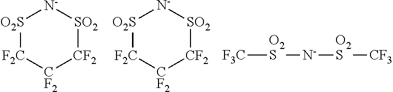 [SMILES: O=S1(=O)[N-]S(=O)(=O)C(F)(F)C(F)(F)C1(F)F ; O=S1(=O)[N-]S(=O)(=O)C(F)(F)C(F)(F)C1(F)F ; O=S(=O)([N-]S(=O)(=O)C(F)(F)F)C(F)(F)F]

The formula (ec1) is as follows.

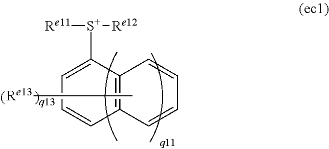

In the formula:
R^{e11} and R^{e12} are each independently a C₁₋₂₀ hydrocarbon group, and the hydrocarbon group may be substituted with —OSO₂—R^{e14}, —SO₂—R^{e14}, —OR^{e14}, —COOR^{e14}, —O—CO—R^{e14}, —O—R^{e15}—COOR^{e14}, —R^{e15}—CO—R^{e14} or —S—R^{e14} (more preferably phenyl, tolyl, trimethylphenyl or naphthyl; further preferably phenyl, tolyl or trimethylphenyl; further more preferably phenyl).
R^{e13} is each independently nitro, hydroxy, halogen, —OSO₂—R^{e14}, —SO₂—R^{e14}, —OR^{e14}, —COOR^{e14}, —O—CO—R^{e14}, —O—R^{e15}—COOR^{e14}, —R^{e15}—CO—R^{e14}, —S—R^{e14} or a C₁₋₂₀ hydrocarbon group, and the hydrocarbon group may be substituted with —OSO₂—R^{e14}, —SO₂—R^{e14}, —OR^{e14}, —COOR^{e14}, —O—CO—R^{e14}, —O—R^{e15}—COOR^{e14}, —R^{e15}—CO—R^{e14} or —S—R^{e14}, R^{e13} is more preferably a C₁₋₂0 hydrocarbon group (further preferably C₁₋₄ alkyl; further more preferably methyl).
R^{e14} is each independently a C₁₋₁₀ hydrocarbon group (preferably methyl, ethyl, i-propyl, n-propyl, tBu, cyclopentyl or cyclohexyl; more preferably methyl or tBu).
R^{e15} is each independently a single bond or a C₁₋₁₀ hydrocarbon group (preferably methyl, ethyl, i-propyl, n-propyl, tBu, cyclopentyl or cyclohexyl; more preferably methyl or tBu).
q11 is a number of 0 to 3 (preferably 0 or 1; more preferably 0).
q13 is a number of 0 to 11 (preferably 0, 1, 2 or 3; more preferably 0, 1 or 3; more preferably 0 or 3).

The formula (ec1) is preferably represented by the following formula (ec1-1).

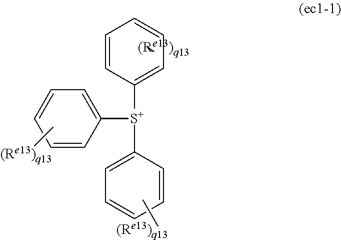

In the formula:
R^{e13} is each independently C₁₋₆ alkyl, C₁₋₆ alkoxy, C₆₋₁₂ aryl, C₆₋₁₂ arylthio or C₆₋₁₂ aryloxy; preferably methyl, ethyl, t-butyl, methoxy, ethoxy, phenylthio or phenyloxy; more preferably t-butyl, methoxy, ethoxy, phenylthio or phenyloxy.
q13 is each independently 0, 1, 2 or 3. It is also a preferred embodiment that all q13 are 1 and all R^{e13} are identical. It is also a preferred embodiment that all q13 are 0. It is also a preferred embodiment that one q13 is 3 and the other two q13 are 0.

Exemplified embodiments of the formula (ec1) include the following.

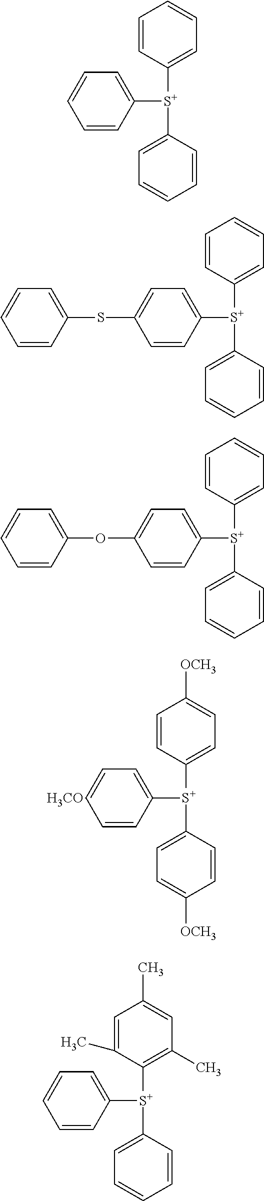 [SMILES: c1ccc([S+](c2ccccc2)c2ccccc2)cc1 ; c1ccc(Sc2ccc([S+](c3ccccc3)c3ccccc3)cc2)cc1 ; c1ccc(Oc2ccc([S+](c3ccccc3)c3ccccc3)cc2)cc1 ; COc1ccc([S+](c2ccc(OC)cc2)c2ccc(OC)cc2)cc1 ; Cc1cc(C)c([S+](c2ccccc2)c2ccccc2)c(C)c1]

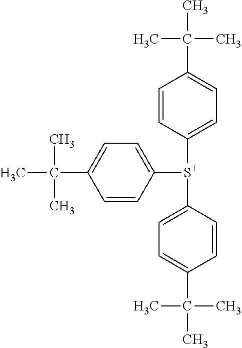 [SMILES: CC(C)(C)c1ccc([S+](c2ccc(C(C)(C)C)cc2)c2ccc(C(C)(C)C)cc2)cc1]

The formula (ec2) is as follows.

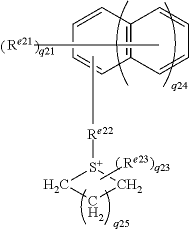

In the formula:
R^{e21} and R^{e23} are each independently nitro, hydroxy, halogen, —OSO₂—R^{e24}, —SO₂—R^{e24}, —OR^{e24}, —COOR^{e24}, —O—CO—R^{e24}, —O—R^{e25}—COOR^{e24}, —R^{e25}—CO—R^{e24}, —S—R^{e24} or a C₁₋₂₀ hydrocarbon group, and the hydrocarbon group may be substituted with —OSO₂—R^{e24}, —SO₂—R^{e24}, —OR^{e24}, —COOR^{e24}, —O—CO—R^{e24}, —O—R^{e25}—COOR^{e24}, —R^{e25}—CO—R^{e24} or —S—R^{e24}.
R^{e22} is a single bond or a C₁₋₂₀ hydrocarbon group, and the hydrocarbon group may be substituted with —OSO₂—R^{e24}, —SO₂—R^{e24}, —OR^{e24}, —COOR^{e24}, —O—CO—R^{e24}, —O—R^{e25}—COOR^{e24}, —R^{e25}—CO—R^{e24} or —S—R^{e24}.
R^{e24} is each independently a C₁₋₁₀ hydrocarbon group,
R^{e25} is each independently a single bond or a C₁₋₁₀ hydrocarbon group.
q21 is a number of 0 to 9.
q23 is a number of 0 to 10.
q24 is a number of 0 to 2.
q25 is a number of 0 to 3.

The formula (ec3) is as follows.

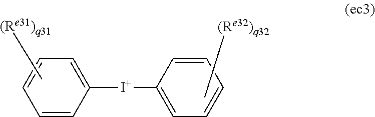

In the formula:
R^{e31} and R^{e32} are each independently nitro, hydroxy, halogen, —OSO₂—R^{e33}, —SO₂—R^{e33}, —OR^{e33}, —COOR^{e33}, —O—CO—R^{e33}, —O—R^{e34}—COOR^{e33}, —R^{e34}—CO—R^{e33}, —S—R^{e33} or a C₁₋₂₀ hydrocarbon group, and the hydrocarbon group may be substituted with —OSO₂—R^{e33}, —SO₂—R^{e33}, —OR^{e33}, —COOR^{e33}, —O—CO—R^{e33}, —O—R^{e34}—COOR^{e33}, —R^{e34}—CO—R^{e33} or —S—R^{e33}. R^{e31} and R^{e32} are preferably C₁₋₁₀ alkyl (more preferably C₁₋₅ alkyl; further preferably C₄₋₅ alkyl).
R^{e33} is each independently a C₁₋₁₀ hydrocarbon group.
R^{e34} is each independently a single bond or a C₁₋₁₀ hydrocarbon group.
q31 is a number of 0 to 5 (preferably 0, 1 or 2; more preferably 1).
q32 is a number of 0 to 5 (preferably 0, 1 or 2; more preferably 1).

Exemplified embodiments of formula (ec3) include the following.

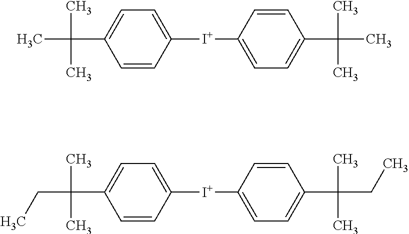

When (E) is a part of the polymer (A), H or F in Anion^{54m-} is substituted and such a part is bonded with other part of the polymer (A). For clarity, explanation is provided using an example. The structure below left is the photoacid generation part (E) but is a part of the polymer (A) and can be read as the unit (A5). In particular, in the formula (a5), R⁵¹=methyl and n52=1. Anion^{54m-} is originally a pentafluorosulfonate ion (the anion below right), then one F is substituted and such a pat is bonded with the polymer (A). Cation^{54m+} is a triphenylsulfonium ion. m=1.

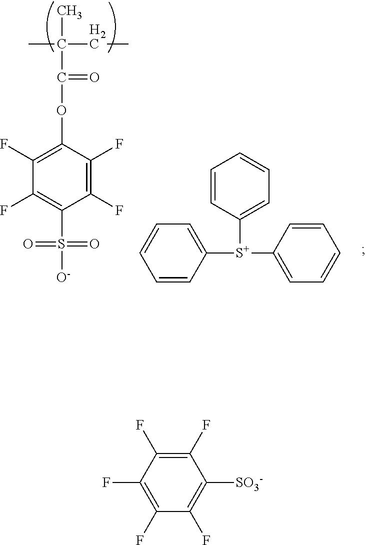

The photoacid generation part (E) may be one type or two or more types (more preferably one type). The content of the photoacid generation part (E) is preferably 0.5 to 20 mass % (more preferably 1 to 15 mass %; further preferably 2 to 10 mass %) based on the total mass of the polymer (A).

When the photoacid generation part (E) is a part of the polymer (A), the content of the photoacid generation part (E) in the composition is calculated as the content of the polymer (A). In this case, the content of the photoacid generation part (E) is 0 mass % based on the total mass of the polymer (A).

### Photoacid Generator (F)

The composition according to the present invention can further comprise a photoacid generator (F). As one preferred embodiment, the photoacid generation part (E) is a component different from (A) to (D) and is a photoacid generator (F). The photoacid generator (F) is preferably represented by the formula (E1) above, and its preferred embodiments are also the same as described above.

The photoacid generator (F) may be one type or two or more types (more preferably one type). The content of the photoacid generator (F) is preferably 0.5 to 20 mass % (more preferably 1 to 15 mass %; further preferably 2 to 10 mass %) based on the total mass of the polymer (A).

### Surfactant (G)

The composition according to the present invention can further comprise a surfactant (G). Coatability can be improved by further comprising a surfactant (G).

Examples of the surfactant (G) that can be used in the present invention include (I) anionic surfactants, (II) cationic surfactants, and (III) nonionic surfactants. More particularly, (I) alkylsulfonates, alkylbenzenesulfonic acids and alkylbenzenesulfonates, (II) laurylpyridinium chloride and laurylmethylammonium chloride, and (III) polyoxyethylene octyl ether, polyoxyethylene lauryl ether and polyoxy ethylene acetylenic glycol ether are preferred.

The surfactant (G) may be one type or two or more types (more preferably one type). The content of the surfactant (G) is preferably 0 to 10 mass % (more preferably 0.5 to 8 mass %; further preferably 1 to 5 mass %) based on the total mass of the polymer (A). It is also a preferred embodiment that the composition of the present invention does not contain the surfactant (G) (0.0 mass %).

### Additive (H)

The composition according to the present invention can further comprise other additive (H) than (A) to (G). The additive (H) is a dye, a lower alcohol, a surface smoothing agent, an acid, a base, a substrate adhesion enhancer, an antifoaming agent, an antiseptic, or any combination of any of these (preferably, a dye, an acid, a base, a substrate adhesion enhancer, or any combination of any of these). When an acid or a base is contained, it is also a preferred embodiment of the present invention to contain only either of them.

The content of the additive (H) is preferably 0 to 10 mass % (more preferably 0 to 5 mass %; further preferably 0.1 to 3 mass %) based on the total mass of the polymer (A). It is also a preferred example of the composition according to the present invention that the additive (H) is not contained (0.0 mass %).

### Method for Manufacturing a Resist Pattern

The method for manufacturing a resist pattern according to the present invention comprises the following steps:
(1) applying a resist underlayer composition above a substrate and heating the resist underlayer composition to form a resist underlayer;
(2) applying a resist composition directly on the resist underlayer and heating the resist composition to form a resist film;
(3) exposing the resist film;
(4) optionally, performing the post-exposure bake of the resist film; and
(5) developing the resist film using a developer to form a resist pattern, provided that the resist underlayer is not developed by the developer.
   In this specification, unless otherwise specified, the numbers in parentheses indicating the steps mean the order.

One embodiment of the manufacturing method according to the present invention is described below.

### Step (1)

In the step (1), a resist underlayer composition is applied above a substrate, and the resist underlayer composition is heated to form a resist underlayer.

The resist underlayer composition is applied above a substrate (for example, a silicon/silicon dioxide-coated substrate, a silicon nitride substrate, a silicon wafer substrate, a glass substrate, an ITO substrate, etc.) by a suitable method.

The contact angle θₛ of the surface of the substrate is preferably less than 900 or greater than 90° (more preferably less than 90°; further preferably less than 85°). The contact angle is measured using water as described later. In order to make the surface of the substrate hydrophobic as described above, a treatment may be performed (for example, HMDS processing).

In the present invention, “above” includes the case of applying directly on a substrate and the case of applying via another layer. For example, a planarization film may be formed directly on a substrate, and the composition according to the present invention may be applied directly on the planarization film. The application method is not particularly limited, but examples thereof include a method of coating with a spinner or coater. After coating, the resist underlayer is formed by heating. Preferably, in the step (1), the resist underlayer composition is applied directly on the substrate.

The resist underlayer composition is preferably the developer tolerant resist underlayer composition described above.

The heating in (1) is performed, for example, by a hot plate. The heating temperature is preferably 100 to 250° C. (more preferably 125 to 225° C.; further preferably 150 to 200° C.). The temperature is the temperature of the heating atmosphere, for example, the temperature of the heating surface of a hot plate. The heating time is preferably 30 to 300 seconds (more preferably 45 to 180 seconds; further preferably 60 to 120 seconds). Heating is preferably carried out in air or nitrogen gas atmosphere. Due to this heating, a cross-linking reaction proceeds in the composition. Therefore, the resist underlayer is not easily dissolved in the subsequent steps.

The film thickness of the resist underlayer is preferably 2 to 50 nm (more preferably 3 to 30 nm; further preferably 5 to 20 nm).

### Step (2)

In the step (2), a resist composition is applied directly on the resist underlayer, and the resist composition is heated to form a resist film.

The method of applying the resist composition is not particularly limited, but may be the same as the above application, and a vapor phase deposition method is also possible. As a more preferred embodiment, a coating method is included.

The resist composition is preferably a metal-containing resist, more preferably an organic metal oxide hydroxide-containing resist, and those described in JP 2021-73367 A can be used. The resist composition is preferably an EUV resist, and in one preferred embodiment, it is a negative-type resist.

The heating temperature in (2) is preferably 75 to 140° C. (more preferably 80 to 130° C.; further preferably 90 to 120° C.). The heating time is preferably 30 to 240 seconds (more preferably 90 to 180 seconds). The heating is preferably carried out in air or nitrogen gas atmosphere.

The thickness of the resist film is preferably 20 to 70 nm (more preferably 25 to 50 nm). Although not to be bound by theory, it is more preferable that the resist underlayer is not dissolved by the resist composition. It can be confirmed that the resist composition is not dissolved by confirming whether or not film thickness reduction has occurred before and after the application of the resist composition.

### Step (3)

In the step (3), the resist film is exposed through a predetermined mask. Although the wavelength of light to be used for exposure is not particularly limited, it is preferable to perform exposure with light having a wavelength of 13.5 to 248 nm. In particular, KrF excimer laser (wavelength: 248 nm), ArF excimer laser (wavelength: 193 nm), extreme ultraviolet ray (wavelength: 13.5 nm), or the like can be used, and extreme ultraviolet ray is preferred. These wavelengths accept a range of ±1%.

It is a preferred embodiment of the present invention that the exposure wavelength passes through the resist film and reaches the resist underlayer. When the resist underlayer composition contains a photoacid generation part (E), it is a preferred embodiment of the present invention that an acid is generated from (E) by the exposure in the step (3).

### Step (4)

After exposure, a post exposure bake (PEB) can be performed as needed. The PEB temperature is preferably 100 to 200° C. (more preferably 150 to 190° C.), and the heating time is preferably 30 to 240 seconds (more preferably 90 to 180 seconds).

Although not to be bound by theory, it is also a preferred embodiment of the present invention that the acid generated from the photoacid generator present in the resist film moves to the resist underlayer, and this acid deprotects the protective group of the polymer (A) in the resist underlayer. It can be thought that in this case, even if the resist underlayer composition of the present invention contains neither photoacid generation part (E) (for example, (E) incorporated in (A) as the unit (A5)) nor the photoacid generator (F), the hydrophilicity of the exposed area of the resist underlayer can be changed.

When the contact angle of the resist film before exposure is defined as θ_{PrR}, that of the resist film after exposure is defined as θ_{PeR}, that of the resist underlayer before exposure is defined as θ_{PrU}, and that of the resist underlayer after exposure is defined as θ_{PeU},
θ_{PeU}/θ_{PrU}<1.0 when θ_{PeR}/θ_{PrR}<1.0, and
θ_{PeU}/θ_{PrU}>1.0 when θ_{PeR}/θ_{PrR}>1.0.

For example, when the hydrophilicity of the resist film is increased by exposure, the contact angle of the resist film becomes smaller. In this case, θ_{PeR}/θ_{PrR}<1.0 because θ_{PeR} changes so as to be decreased from θ_{PrR}. It is preferable that in the manufacturing method of the present invention, the hydrophilicity of the resist underlayer changes so as to match the hydrophilicity of the resist film. That is, when the hydrophilicity of the resist film increases (θ_{PeR} changes so as to be decreased from θ_{PrR}), it is preferable that the hydrophilicity of the resist underlayer also increases (θ_{PeU} changes so as to be decreased from θ_{PrU}). Moreover, when the hydrophilicity of the resist film is decreased (the hydrophobicity is increased) by exposure, it is preferable that the hydrophilicity of the resist underlayer is also decreased. Since change of the hydrophilicity is performed by deprotection of the protective group with acid, it is preferred that the hydrophilicity of the exposed area changes.

A more preferable embodiment of the present invention is that θ_{PeR}/θ_{PrR}<1.0 and θ_{PeU}/θ_{PrU}<1.0.

The contact angle is measured using water. Preferably, the contact angle is measured by dropping 2p L of water onto the resist film or the resist underlayer and using a contact angle meter.

### Step (5)

Development of the exposed resist film is performed using a developer to form a resist pattern. Examples of the development include an alkali development and an organic solvent development or the like, and the organic solvent development is preferred. The developer comprises an organic solvent, and more preferably it consists of an organic solvent. In the case of organic solvent development, the developer includes hydrocarbon solvents, ether solvents, ester solvents, ketone solvents and alcohol solvents, preferably ester solvents or ketone solvents. Exemplified embodiments of the developer include 2-heptanone, butyl acetate, PGMEA and the like.

By means of using such a developer, the resist layer can be developed. On the other hand, the developer does not develop the resist underlayer. Although not to be bound by theory, it can be thought that the resist underlayer is not developed because the cross-linking agent (B) and the polymer (A) are cross-linked. “Not developed” can be confirmed by the following operation. The amount of decrease in the thickness of the resist underlayer is 0 to 30% and/or 5 nm or less when the developer is paddled on the resist underlayer for 30 seconds. “Developer tolerance” can also be confirmed by the above-described operation.

Although not to be bound by theory, it can be thought that by having the resist underlayer of the present invention, the hydrophilicity of the resist underlayer changes in accordance with the change in the hydrophilicity of the resist film, thereby preventing the collapse of the resist pattern due to the decrease in affinity with the substrate. Although not to be bound by theory, it can be thought that the hydrophilicity of the resist underlayer in the exposed area or unexposed area changes in accordance with the resist film, so that the sufficient affinity of the resist pattern and the resist underlayer can be maintained. Although not to be bound by theory, it can be thought that the exposed area and unexposed area of the resist underlayer are physically connected even after development, so even if the affinity in a part of the resist underlayer with the substrate is reduced, the resist underlayer can entirely maintain the adhesion to the substrate as a whole resist underlayer.

The method for manufacturing a resist pattern can further comprises a following step:
(6) washing the resist pattern with a cleaning liquid and removing the cleaning liquid from between the patterns.

A cleaning liquid can be used to clean the resist pattern in order to remove localized film residues. As the cleaning liquid, water or organic solvents (for example, IPA, PGME, PGMEA, PGEE, nBA are included) are included. In a preferred embodiment of the present invention, the cleaning liquid is a rinse liquid, and cleaning is performed by replacing the developer with the rinse liquid. Examples of the rinse liquid include those described in JP 2019-519804 A and WO 2021/204651 A1.

The method for manufacturing a processed substrate according to the present invention comprises the following steps:
forming a resist pattern by the above-described method; and
(7) processing using the resist pattern as a mask.

Preferably, in the step (7), the resist underlayer and/or the substrate is processed. It is also possible to process the substrate by etching the resist underlayer and the substrate at once, or to process the substrate stepwise by etching the resist underlayer and then etching the substrate using it as a mask. More preferably, the resist underlayer and the substrate are etched at once. Etching may be either dry etching or wet etching. This allows a gap to be formed on the substrate or a layer on the substrate. After forming the gap, the resist pattern can be removed by contacting with water, a mixture of a water-soluble organic solvent and water, or an alkaline aqueous solution. It is also possible to process the substrate by methods other than etching.

After that, if necessary, the substrate is further processed to form a device. These further processing can be performed by applying well-known methods. Preferably, the method further comprises a step of forming a wiring on the processed substrate. If necessary, the substrate is cut into chips, connected to lead frames, and packaged with resin. In the present invention, this packaged product is called a device. Preferably, the device is a semiconductor device.

### Example

The present invention is described below with reference to various examples. The embodiments of the present invention are not limited only to these examples.

In the following Examples, the mass average molecular weight (Mw) is measured by gel permeation chromatography (GPC) using polystyrene as a standard. GPC is measured using Alliance™ e2695 type high-speed GPC system (Nihon Waters) and organic solvent-based GPC column Shodex KF-805L (Showa Denko). The measurement is performed using monodispersed polystyrene as a standard sample and chloroform as an eluent, under the measuring conditions of a flow rate of 0.6 ml/min and a column temperature of 40° C., and Mw is calculated as a relative molecular weight to the standard sample.

### Synthesis of Polymer 2

95.8 g of p-acetoxystyrene as a monomer that derives the unit (A2) after being deprotected, 37.8 g of t-butyl acrylate as a monomer that derives the unit (A1), and 10.3 g of styrene as a monomer that derives the unit (A3), as well as 6 g of azobisisobutyronitrile (AIBN) and 1 g of t-dodecylmercaptan as polymerization initiators are dissolved in 230 g of PGME, and the polymerization is conducted at 70° C. for 16 hours in a nitrogen atmosphere. After the polymerization is completed, the reaction solution is added dropwise to a large amount of hexane to solidify/purify the formed polymer. Next, 150 g of PGME is added to the polymer thus purified, and then 300 g of methanol, 80 g of triethylamine and 15 g of water are further added, and the hydrolysis reaction is carried out for 8 hours while heating under reflux. After the reaction is completed, the solvent and triethylamine are evaporated under reduced pressure. The polymer obtained is then dissolved in acetone. This solution is added dropwise to a large amount of distilled water with stirring to solidify. The white solid formed is filtered and then dried under reduced pressure at 50° C. overnight. Polymer 2 thus obtained is a random copolymer with a mass average molecular weight (Mw) of 12,000 and a polydispersity index (PDI) of 1.6, and its ¹³C-NMR analysis indicates that a molar ratio of vinylphenol-derived unit, t-butyl acrylate-derived unit and styrene-derived unit is 60:30:10.

### Synthesis of Polymer 6

16.7 g of 4-vinylphenol as a monomer that derives the unit (A2), 3.0 g of triphenylsulfonium 2,3,5,6-tetrafluoro-4-(methacryloyloxy)benzenesulfonic acid as a monomer that derives the unit (A5), 27.9 g of 2-ethyl-2-adamantyl methacrylate as a monomer that derives the unit (A1) and 2.1 g of AIBN as a polymerization initiator are dissolved in 76 g of anhydrous tetrahydrofuran and acetonitrile (volume ratio=1:1), and the polymerization is conducted at 65° C. for 24 hours in a closed pressure vessel. After the polymerization is completed, the reaction solution is added dropwise to a large amount of diethyl ether with stirring to solidify the polymer. The white solid formed is filtered and then dried under reduced pressure at 50° C. overnight. The dried white solid is then dissolved in tetrahydrofuran and the solution is added dropwise with stirring to a large amount of diethyl ether to solidify the polymer again, which is filtered. The resulting white solid is dissolved in tetrahydrofuran and the solution is added dropwise with stirring to a large amount of diethyl ether to solidify the polymer again, which is filtered. The solid obtained is dried under reduced pressure at 50° C. overnight. Polymer 6 thus obtained is a random copolymer of Mw=4,000 and PDI=1.6, and its ¹³C-NMR analysis indicates that a molar ratio of 4-vinylphenol-derived unit, 2-ethyl-2-adamantyl methacrylate-derived unit and triphenylsulfonium 2,3,5,6-tetrafluoro-4-(methacryloyloxy)benzenesulfonic acid-derived unit is 65:30:5.

### Synthesis of Polymers 1, 3 to 5 and 7

Polymers 1, 3 to 5 and 7 are synthesized in the same manner as the synthesis of Polymer 2 above, except that the monomers and molar ratios are changed. The polymers after synthesis are described in Table 1.

TABLE 1

| Table | Structure | Mw | PDI |
|---|---|---|---|
| Polymer 1 | 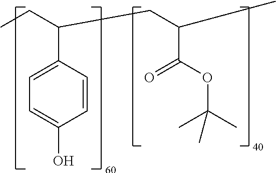 | 13,000 | 1.7 |
| Polymer 2 | 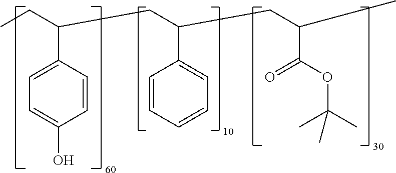 | 12,000 | 1.6 |
| Polymer 3 | 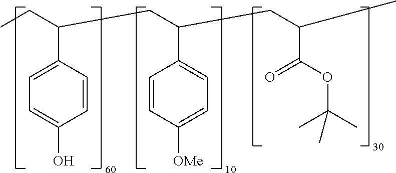 | 12,500 | 1.7 |
| Polymer 4 | 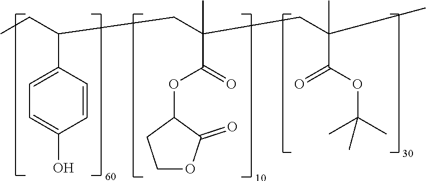 | 15,000 | 1.8 |
| Polymer 5 | 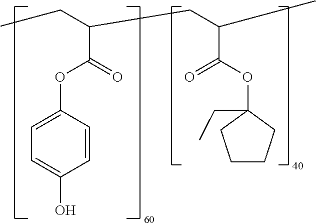 | 18,000 | 1.6 |
| Polymer 6 | 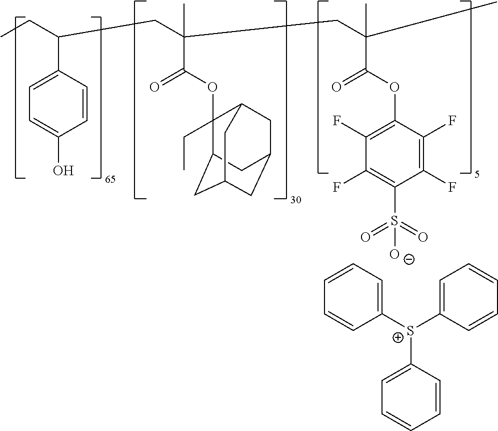 | 4,000 | 1.6 |
| Polymer 7 | 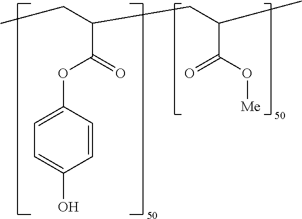 | 19,500 | 1.8 |

### Preparation of the Composition of Example 1

By mixing so as to make a mass ratio of PGMEA:PGME:EL is 30:40:30, Solvent 1 is obtained. 100 mass parts of the above Polymer 1, 30 mass parts of Cross-linking agent 1, 5 mass parts of Thermal acid generator 1 and 5 mass parts of Photoacid generator 1 are added to Solvent 1, and the solid component concentration is adjusted to become 0.385 mass %. Components other than the solvent are solid components. This is stirred at room temperature for 30 minutes. It is visually confirmed that the solid components are completely dissolved. Filtration is carried out through a 0.2 μm pore size filter. This gives the composition of Example 1.

Cross-linking agent 1 is as follows.

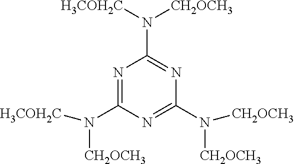

Thermal acid generator 1 is a mixture of malonic acid:triethylamine=1:2.

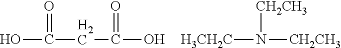

Photoacid generator 1 is diphenyl-2,4,6-trimethyl-phenylsulfonium p-toluenesulfonic acid.

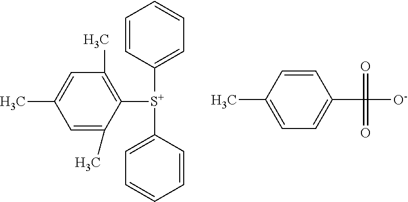

Preparation of the compositions of Examples 2 to 6 and Comparative Example 1

The compositions of Examples 2 to 6 and Comparative Example 1 are prepared in the same manner as the composition of Example 1, except that each component and its compounding ratio are changed as described in Table 2. The solid component concentration is 0.385 mass % as in Example 1 for all compositions.

TABLE 2

| | | | | | | | | | | | | | Evaluation | |
|---|---|---|---|---|---|---|---|---|---|---|---|---|---|---|
| | | Composition | | | | | | | | | | | Pattern | Solvent |
| | | (A) | | (B) | | (C) | | (D) | (F) | | (G) | | collapse | resistance |
| Example | 1 | Polymer 1 | 100 | Cross- | 30 | Thermal | 5 | Solvent 1 | Photoacid | 5 | — | | A | A |
| | | | | linking | | acid | | | generator | | | | | |
| | | | | agent 1 | | generator 1 | | | 1 | | | | | |
| | 2 | Polymer 2 | 100 | Cross- | 30 | Thermal | 5 | Solvent 1 | Photoacid | 5 | Surfac- | 0.0005 | A | A |
| | | | | linking | | acid | | | generator | | tant 1 | | | |
| | | | | agent 2 | | generator 1 | | | 1 | | | | | |

| | 3 | Polymer 3 | 100 | Cross- | 30 | Thermal | 5 | Solvent 1 | Photoacid | 5 | — | A | A |
|---|---|---|---|---|---|---|---|---|---|---|---|---|---|
| | | | | linking | | acid | | | generator | | | | |
| | | | | agent 3 | | generator 1 | | | 1 | | | | |
| | 4 | Polymer 4 | 100 | Cross- | 30 | Thermal | 5 | Solvent 1 | Photoacid | 5 | — | A | B |
| | | | | linking | | acid | | | generator | | | | |
| | | | | agent 4 | | generator 1 | | | 1 | | | | |
| | 5 | Polymer 5 | 100 | Cross- | 30 | Thermal | 5 | Solvent 1 | Photoacid | 5 | — | A | B |
| | | | | linking | | acid | | | generator | | | | |
| | | | | agent 1 | | generator 1 | | | 1 | | | | |
| | 6 | Polymer 6 | 100 | Cross- | 30 | Thermal | 5 | Solvent 2 | — | | — | A | A |
| | | | | linking | | acid | | | | | | | |
| | | | | agent 1 | | generator 1 | | | | | | | |
| Comparative | 1 | Polymer 7 | 100 | Cross- | 30 | Thermal | 5 | Solvent 1 | Photoacid | 5 | — | B | B |
| Example | | | | linking | | acid | | | generator | | | | |
| | | | | agent 1 | | generator 1 | | | 2 | | | | |

In the table:

Polymers 1 to 7, Cross-linking agent 1, Thermal acid generator 1, Photoacid generator 1 and Solvent 1 are as described above.

Cross-linking agent 2 is as follows.

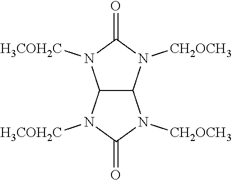

Cross-linking agent 3 is as follows.

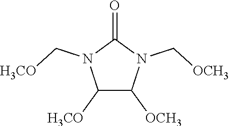 [SMILES: COCN1C(=O)N(COC)C(OC)C1OC]

Cross-linking agent 4 is as follows.

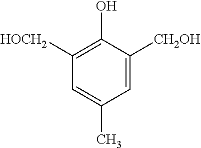

Solvent 2 is a mixed solvent mixed so as to the mass ratio of PGMEA:PGME:EL becomes 20:50:30.

Photoacid generator 2 is triphenylsulfonium trifluoromethanesulfonate.

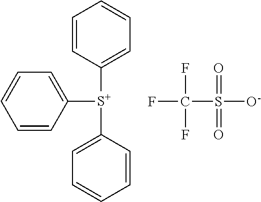 [SMILES: c1ccc([S+](c2ccccc2)c2ccccc2)cc1 ; O=S(=O)([O-])C(F)(F)F]

Surfactant 1 is an acetylenic diol polyoxyalkylene ether and represented by the following.

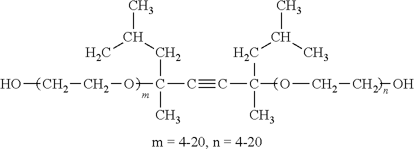 [SMILES: CC(C)CC(C)(C#CC(C)(CC(C)C)OCCO)OCCO]

### Evaluation of Pattern Collapse

Each composition prepared above is applied onto a silicon substrate by spin coating. This is heated on a hot plate at 170° C. for 90 seconds for cross-linking reaction to obtain a resist underlayer (thickness: 10 nm). Then, a solution of 4-methyl-2-pentanol and an organometal tin oxy hydroxide resist composition is spin-coated on the resist underlayer and heated at 100° C. for 2 minutes to form a Sn resist film (thickness: 35 nm). This substrate is exposed to extreme ultraviolet ray having a wavelength of 13.5 nm so as to form a pattern of lines of 16 nm and spaces of 16 nm. This substrate is subjected to PEB at 170° C. for 2 minutes in an air atmosphere using a hot plate. The resist film on the substrate is paddle-developed using 2-heptanone for 30 seconds. The wafer is spined at high speed and dried. A SEM (0.5 μm×0.5 μm) photograph of the resist pattern is taken. The space size of the resist pattern is 16 nm. Pattern collapse prevention performance is evaluated using CG4000 (Hitachi High Technologies). Evaluation criteria are as described below. The results obtained are as described in Table 2.
A: No pattern collapse is observed.
B: Pattern collapse is observed.

Although not to be bound by theory, it can be thought that since Polymer 7 of Comparative Example 1 has no unit having a protective group that is deprotected by an acid, the hydrophilicity does not change even if an acid is generated from the photoacid generator.

### Evaluation of Solvent Resistance

Each composition prepared above is applied onto a silicon substrate by spin coating. This is heated on a hot plate at 170° C. for 90 seconds for cross-linking reaction to obtain a resist underlayer (thickness: 10 nm). The insolubility of this underlayer in 4-methyl-2-pentanol and 2-heptanone is confirmed by the following test.

4-methyl-2-pentanol is filled up on the resist underlayer and left to stand for 30 seconds. This is spin-dried and an SEM section is formed. Film thickness measurement is performed using an ellipsometer. The same test is performed by changing the liquid from 4-methyl-2-pentanol to 2-heptanone. Evaluation criteria for solvent resistance are as follows. The results obtained are listed in Table 2.
A: With any liquid, film thickness reduction of the resist underlayer is not observed or is less than 1 nm.
B: With at least one of the liquids, film thickness reduction of 1 to 2 nm is observed.
C: With at least one of the liquids, film thickness reduction larger than 2 nm is observed.

Although not to be bound by theory, it can be thought that using the resist underlayer of the present invention, the film thickness reduction due to the resist composition and developer can be suppressed.

1. A developer tolerant resist underlayer composition comprising a polymer (A), a cross-linking agent (B), a thermal acid generator (C) and a solvent (D):
wherein the polymer (A) comprises at least a unit having a protective group that is deprotected by an acid, and wherein the hydrophilicity of the portion where the deprotected unit is present changes after exposure.

2. The composition according to claim 1, wherein the polymer (A) comprises a unit (A1) represented by the formula (a1): 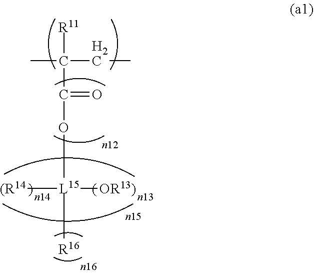
wherein
R¹¹ is each independently H or methyl,
L¹⁵ is each independently a C₆₋₂₀ aromatic hydrocarbon group or a C₁₋₆ saturated hydrocarbon group,
R¹³ is each independently tert-butyl or C₅₋₁₀ alkyl (where the methylene in the alkyl may be replaced with oxy and/or carbonyl),
R¹⁴ is each independently C₁₋₅ alkyl,
R¹⁶ is each independently tert-butyl or C₅₋₁₅ alkyl, and
n12, n15 and n16 are each independently a number of 0 to 1,
n13 is each independently a number of 1 to 3, and
n14 is each independently a number of 0 to 4,
provided that n12=n16=1 when n15=0, and n16=0 when n15=1.

3. The composition according to claim 2, wherein the polymer (A) further comprises at least one unit (A2) represented by formula (a2), a unit (A3) represented by formula (a3), a unit (A4) represented by formula (a4) and a unit (A5) represented by formula (a5): 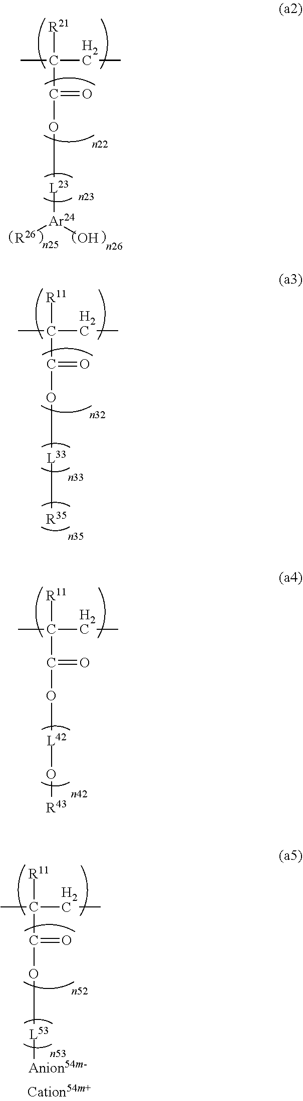
wherein
in the formula (a2):
R²¹ is each independently H or methyl,
L²³ is each independently C₁₋₁₀ alkylene,
Ar²⁴ is each independently C₆₋₂₀ aryl,
R²⁶ is each independently C₁₋₅ alkyl,
n22 and n23 are each independently a number of 0 to 1,
n25 is each independently a number of 0 to 4, and
n26 is each independently a number of 1 to 3;
in the formula (a3):
R³¹ is each independently H or methyl,
L³³ is each independently C₁₋₁₀ alkylene,
Ar³⁴ is each independently C₆₋₂₀ aryl,
R³⁵ is each independently —O—R^{35a}, (C═O)—R^{35b}, —(C═O)—O—R^{35a}, —(C═O)—NR^{35c}R^{35d}, —O—(C═O)—R^{35e}, —NR^{35f}—(C═O)—R^{35g} or —R^{35j}OH,
n32 and n33 are each independently a number of 0 to 1,
n35 is each independently a number of 0 to 3,
R^{35a} is each independently C₁₋₄ alkyl (excluding tert-butyl),
R^{35b} is each independently H or C₁₋₄ alkyl,
R^{35c} and R^{35d} are each independently H or C₁₋₄ alkyl, and when both R^{35c} and
R^{35d} are alkyl, these may be combined to form a ring,
R^{35e} is each independently H, C₁₋₄ alkyl or C₁₋₄ alkoxy (excluding tert-butoxy),
R^{35f} is each independently H or C₁₋₄ alkyl,
R^{35g} is each independently H, C₁₋₄ alkyl or —NR^{35h}R^{35r},
R^{35h} and R^{35r} are each independently H or C₁₋₄ alkyl, and when both R^{35h} and R^{35r} are alkyl, these may be combined to form a ring, and
R^{35j} is each independently C₁₋₄ alkylene;
in the formula (a4):
R⁴¹ is each independently H or methyl,
L⁴² is C₁₋₄ alkylene,
n42 is a number of 0 to 1,
R⁴³ is C₁₋₄ alkyl (excluding tert-butyl) or the following group: 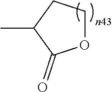
wherein
n43 is a number of 1 to 2; and
in the formula (a5):
R⁵¹ is each independently H or methyl,
L⁵³ is each independently C₁₋₁₀ alkylene,
n52 and n53 are each independently a number of 0 to 1,
anion^{54m-} is an m-valent anion that is bonded upward in the formula,
cation^{54m+} is an m-valent cation that is ionically bonded with anions, and
m is a number of 1 to 2.

4. The composition according to claim 3, which satisfies, when the number of repetitions of the unit (A1), the unit (A2), the unit (A3), the unit (A4) and the unit (A5) are respectively nA1, nA2, nA3, nA4 and nA5, the following:
$$5 \% \leq nA 1 / ( nA 1 + nA 2 + nA 3 + nA 4 + nA 5 ) \leq 100 \% ,$$
$$0 \% \leq nA 2 / ( nA 1 + nA 2 + nA 3 + nA 4 + nA 5 ) \leq 95 \% ,$$
$$0 \% \leq nA 3 / ( nA 1 + nA 2 + nA 3 + nA 4 + nA 5 ) \leq 95 \% ,$$
$$0 \% \leq nA 4 / ( nA 1 + nA 2 + nA 3 + nA 4 + nA 5 ) \leq 95 \% , and$$
$$0 \% \leq nA 5 / ( nA 1 + nA 2 + nA 3 + nA 4 + nA 5 ) \leq 95 \% .$$

5. The composition according to claim 2, wherein the unit (A1) has a protective group that is deprotected by an acid and is deprotected after exposure.

6. The composition according to claim 1, wherein the cross-linking agent (B) is represented by the formula (b1): 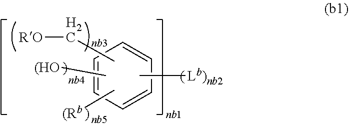
wherein
nb1 is 1, 2, 3 or 4,
nb2 is 0 when nc1 is 1, and 1 when nc1 is 2 or more,
nb3 is 0, 1 or 2,
nb4 is 1 or 2,
nb5 is 0 or 1,
L^{b} is a single bond or a C₁₋₃₀ hydrocarbon group,
R^{b} is each independently C₁₋₆ alkyl (where the methylene in the alkyl may be replaced with oxy) or C₆₋₁₀ aryl, and
R′ is H or methyl.

7. The composition according to claim 1, wherein the thermal acid generator (C) is represented by the formula (c1): 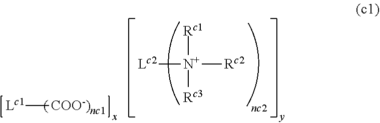
wherein
nc1 is 1 or 2,
L^{c1} is H or C₁₋₆ alkyl when nc1 is 1, in which the alkyl may be substituted with halogen or hydroxy, and C₁₋₄ alkylene when nc1 is 2, in which the alkylene may be substituted by halogen or hydroxy, and the methylene in the alkylene may be replaced with carbonyl, oxy or amido,
nc2 is 1 or 2,
L^{c2} is C₁₋₆ alkyl when nc2 is 1, in which the alkyl may be substituted with halogen or hydroxy, and C₁₋₄ alkylene when nc2 is 1, in which the alkylene may be substituted with halogen or hydroxy, and the methylene in the alkylene may be replaced with carbonyl, oxy or amido;
R^{c1}, R^{c2} and R^{c3} are each independently H or C₁₋₁₀ alkyl, in which the alkyl may be substituted with halogen or hydroxy, and
x and y are 1 or 2, provided that nc1 X x=nc2 X y is satisfied.

8. The composition according to claim 1, wherein the solvent (D) is water, a hydrocarbon solvent, an ether solvent, an ester solvent, an alcohol solvent, a ketone solvent, or any combination of any of these.

9. The composition according to claim 1, further comprising a photoacid generation part (E), which may optionally be a part of the polymer (A) or which may optionally be a component different from (A) to (D).

10. The composition according to claim 9, wherein a pKa (H₂O) of the acid generated from the thermal acid generator (C) is greater than that of a acid generated from the photoacid generation part (E).

11. The composition according to claim 9, wherein the photoacid generation part (E) is represented by the formula (E1) (provided that when the photoacid generation part (E) is a part of the polymer (A), H or F in Anion^{54m-} is substituted and such a part is bonded with other part of the polymer (A)):
Anion^{54m-} Cation^{54m+} (E1)
wherein
anion^{54m-} is an anion selected from the group consisting of an anion represented by the formula (ea1) and an anion represented by the formula (ea2), and is m-valent as a whole,
cation^{54m+} is a cation selected from the group consisting of a cation represented by the formula (ec1), a cation represented by the formula (ec2) and a cation represented by the formula (ec3), and is m-valent as a whole: 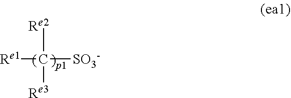
wherein
R^{e1} is a C₄₋₃₀ hydrocarbon group containing a ring structure having 5 or more ring atoms, in which at least one of the ring atoms may be nitrogen, the hydrocarbon group may be substituted with nitro, hydroxy, halogen, —OSO₂—R^{e4}, —SO₂—R^{e4}, —OR^{e4}, —COOR^{e4}, —O—CO—R^{e4}, —O—R^{e5}—COOR^{e4}, —R^{e5}—CO—R^{e4} or —S—R^{e5}, and —CH₂— in the hydrocarbon group may be replaced with carbonyl, ether, carbonyloxy, sulfide, thiocarbonyl or sulfonyl,
R^{e2} and R^{e3} are each independently H, fluorine, fluorine-substituted C₁₋₅ alkyl or C₁₋₅ alkyl,
R^{e4} is each independently a C₁₋₁₀ hydrocarbon group,
R^{e5} is each independently a single bond or a C₁₋₁₀ hydrocarbon group, and
p1 is each independently a number of 0 to 10; 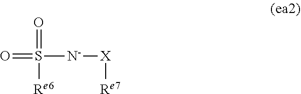
wherein
X is carbonyl or sulfonyl, and
R^{e6} and R^{e7} are each independently C₁₋₆ fluorine-substituted alkyl, C₁₋₆ fluorine-substituted alkoxy, C₆₋₁₂ fluorine-substituted aryl, C₂₋₁₂ fluorine-substituted acyl or C₆₋₁₂ fluorine-substituted alkoxyaryl, in which R^{e6} and R^{e7} may be bonded to each other to form a fluorine-substituted heterocyclic structure; 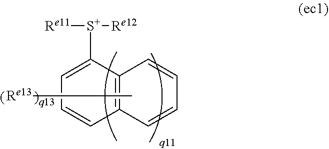
wherein
R^{e11} and R^{e12} are each independently a C₁₋₂₀ hydrocarbon group, and the hydrocarbon group may be substituted with —OSO₂—R^{e14}, —SO₂—R^{e14}, —OR^{e14}, —COOR^{e14}, —O—CO—R^{e14}, —O—R^{e15}—COOR^{e14}, R^{e15}—CO—R^{e14} or —S—R^{e14},
R^{e13} is each independently nitro, hydroxy, halogen, —OSO₂—R^{e14}, —SO₂—R^{e14}, —OR^{e14}, —COOR^{e14}, —O—CO—R^{e14}, —O—R^{e15}—COOR^{e14}, —R^{e15}—CO—R^{e14}, —S—R^{e14} or a C₁₋₂₀ hydrocarbon group, and the hydrocarbon group may be substituted with —OSO₂—R^{e14}, —SO₂—R^{e14}, —OR^{e14}, —COOR^{e14}, —O—CO—R^{e14}, —O—R^{e15}—COOR^{e14}, —R^{e15}—CO—R^{e14} or —S—R^{e14},
R^{e14} is each independently a C₁₋₁₀ hydrocarbon group,
R^{e15} is each independently a single bond or a C₁₋₁₀ hydrocarbon group,
q1 is a number of 0 to 3, and
q13 is a number of 0 to 11; 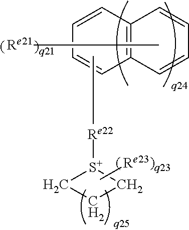
wherein
R^{e21} and R^{e23} are each independently nitro, hydroxy, halogen, —OSO₂—R^{e24}, —SO₂—R^{e24}, —OR^{e24}, —COOR^{e24}, —O—CO—R^{e24}, —O—R^{e25}—COOR^{e24}, —R^{e25}—CO—R^{e24}, —S—R^{e24} or a C₁₋₂₀ hydrocarbon group, and the hydrocarbon group may be substituted with —OSO₂—R^{e24}, —SO₂—R^{e24}, —OR^{e24}, —COOR^{e24}, —O—CO—R^{e24}, —O—R^{e25}—COOR^{e24}, —R^{e25}—CO—R^{e24} or —S—R^{e24},
R^{e22} is a single bond or a C₁₋₂₀ hydrocarbon group, and the hydrocarbon group may be substituted with —OSO₂—R^{e24}, —SO₂—R^{e24}, —OR^{e24}, —COOR^{e24}, —O—CO—R^{e24}, —O—R^{e25}—COOR^{e24}, —R^{e25}—CO—R^{e24} or —S—R^{e24},
R^{e24} is each independently a C₁₋₁₀ hydrocarbon group,
R^{e25} is each independently a single bond or a C₁₋₁₀ hydrocarbon group,
q21 is a number of 0 to 9,
q23 is a number of 0 to 10,
q24 is a number of 0 to 2, and
q25 is a number of 0 to 3; and 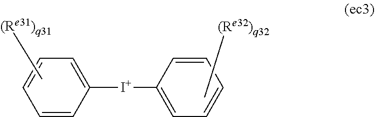
wherein
R^{e31} and R^{e32} are each independently nitro, hydroxy, halogen, —OSO₂—R^{e33}, —SO₂—R^{e33}, —OR^{e33}, —COOR^{e33}, —O—CO—R^{e33}, —O—R^{e34}—OR^{e33}, —R^{e34}—CO—R^{e33}, —S—R^{e33} or a C₁₋₂₀ hydrocarbon group, and the hydrocarbon group may be substituted with —OSO₂—R^{e33}, —SO₂—R^{e33}, —OR^{e33}, —COOR^{e33}, —O—CO—R^{e33}, —O—R^{e34}—COOR^{e33}, —R^{e34}—CO—R^{e33} or —S—R^{e33},
R^{e33} is each independently a C₁₋₁₀ hydrocarbon group,
R^{e34} is each independently a single bond or a C₁₋₁₀ hydrocarbon group,
q31 is a number of 0 to 5, and
q32 is a number of 0 to 5.

12. The composition according to claim 1, further comprising a surfactant (G).

13. The composition according to claim 1, further comprising an additive (H):
wherein the additive (H) is a dye, a lower alcohol, a surface smoothing agent, an acid, a base, a substrate adhesion enhancer, an antifoaming agent, an antiseptic, or any combination of any of such.

14. The composition according to claim 1,
wherein
a content of the polymer (A) is 0.1 to 10 mass % based on the total mass of the composition,
a content of the cross-linking agent (B) is 5 to 100 mass % based on the total mass of the polymer (A),
a content of the thermal acid generator (C) is 0.5 to 30 mass % based on the total mass of the polymer (A), or
a content of the solvent (D) is 80 to 99.99 mass % based on the total mass of the composition.

15. The composition according to claim 1, wherein the developer comprises an organic solvent.

16. The composition according to claim 1, wherein the resist is a metal-containing resist.

17. A method for manufacturing a resist pattern comprising the following steps:
(1) applying a resist underlayer composition above a substrate and heating the resist underlayer composition to form a resist underlayer;
(2) applying a resist composition directly on the resist underlayer and heating the resist composition to form a resist film;
(3) exposing the resist film;
(4) optionally, performing the post-exposure bake of the resist film; and
(5) developing the resist film using a developer to form a resist pattern, provided that the resist underlayer is not developed by the developer:
wherein
when the contact angle of the resist film before exposure is defined as θ_{PrR}, that of the resist film after exposure is defined as θ_{PeR}, that of the resist underlayer before exposure is defined as θ_{PrU}, and that of the resist underlayer after exposure is defined as θ_{PeU},
θ_{PeU}/θ_{PrU}<1.0 when θ_{PeR}/θ_{PrR}<1.0, and
θ_{PeU}/θ_{PrU}>1.0 when θ_{PeR}/θ_{PrR}>1.0,
wherein the contact angle is measured using water.

18. The method according to claim 17, wherein the resist underlayer composition is a developer tolerant resist underlayer composition according to one or more of claims 1 to 16 comprising:
a polymer (A), a cross-linking agent (B), a thermal acid generator (C) and a solvent (D):
wherein the polymer (A) comprises at least a unit having a protective group that is deprotected by an acid, and wherein the hydrophilicity of the portion where the deprotected unit is present changes after exposure.

19. The method according to claim 17, wherein the contact angle is measured by dropping 2 μL of water onto the resist film or the resist underlayer and using a contact angle meter.

20. The method according to claim 17, wherein the contact angle θₛ of the surface of the substrate is less than 90° or greater than 90°.

21. The method according to claim 17, wherein the acid generated in the steps (3) and (4) moves to the resist underlayer to cause a change from θ_{PrU} to θ_{PeU}.

22. The method according to claim 17, further comprising a step (6):
(6) washing the resist pattern with a cleaning liquid and removing the cleaning liquid from between the patterns.

23. A method for manufacturing a processed substrate comprising the following steps:
forming a resist pattern by the method according to claim 17; and
(7) processing using the resist pattern as a mask.

24. A method for manufacturing a device comprising the method according to claim 17.
